(19) United States
(12) Patent Application Publication
(10) Pub. No.: US 2008/0171289 A1
(43) Pub. Date: Jul. 17, 2008

(54) Planographic Printing Plate Material and Printing Process

(76) Inventor: Tatsuichi Maehashi, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/885,758

(22) PCT Filed: Feb. 10, 2006
(86) PCT No.: PCT/JP2006/302328

§ 371 Date: Sep. 6, 2007

(30) Foreign Application Priority Data
Mar. 10, 2005 (JP) 2005-066897

(51) Int. Cl. G03F 7/12; G03F 7/004

(52) U.S. Cl. 430/286.1; 430/302

(57) ABSTRACT

The invention provides a planographic printing plate material that excels in on-press development property, printing durability, sensitivity and resistance to fogging by pressure, and a printing process employing the planographic printing plate material. As a means thereof, a planographic printing plate material of on-press development type is used which comprises a support and provided thereon, a hydrophilic layer and a thermosensitive image formation layer, wherein the thermosensitive image formation layer contains heat fusible particles in an amount of not less than 10% by weight based on the total solid content of the thermosensitive image formation layer, the heat fusible particles comprising a heat melting compound having a melting point of from 60 to 100° C. and a heat softening compound having a softening point of from 70 to 150° C.

### FIELD OF THE INVENTION

The present invention relates to a planographic printing plate material, which is developed on a printing press after an image is recorded, and a printing process employing the same.

### TECHNICAL BACKGROUND

In recent years, a computer to plate (CTP) system, in which image data can be directly recorded in a printing plate material, has been widely used in conjunction with the digitization of printing data. As a usable printing plate material for CTP, there are a printing plate material comprising an aluminum support such as a conventional PS plate, and a flexible printing plate material comprising a flexible resin film sheet and provided thereon, various functional layers.

Recently, in the commercial printing industries, there is a tendency that many kinds of prints are printed in a small amount, and an inexpensive printing plate material with high quality has been required in the market. As a conventional flexible printing plate material, there are a silver salt diffusion transfer type printing plate material as disclosed in Japanese Patent O.P.I. Publication No. 5-66564, in which a silver salt diffusion transfer type light sensitive layer is provided on a flexible sheet; a printing plate material as disclosed in Japanese Patent O.P.I. Publication Nos. 8-507727, 6-186750, 6-199064, 7-314934, 10-58636 and 10-244773 in which a hydrophilic layer and a lipophilic layer, one of which is the outermost layer, are provided on a flexible sheet where the outermost layer is ablated by laser exposure to prepare a printing plate; and a printing plate material as disclosed in Japanese Patent O.P.I. Publication No. 2001-96710 in which a hydrophilic layer and a heat melt image formation layer are provided on a flexible sheet where a hydrophilic layer or a heat melt image formation layer is imagewise heated by laser exposure to heat-fix the image formation layer onto the hydrophilic layer.

As an image formation method in printing, there is known a so-called on-press development from the environmental viewpoint, in which when a printing plate material after image writing (imagewise exposure) is mounted on an off-set press, and dampening water is supplied to the printing plate material during printing, only the image formation layer at non-image portions is swollen or dissolved by the dampening water, and transferred to a printing paper (paper waste) at initial printing, whereby the image formation layer at non-image portions is removed (see Patent Documents 1 and 2). The printing plate material capable of being subjected to on-press development provides images with sharp dots and high precision without requiring a specific development after exposure, and excels in environmental protection.

However, this printing plate material has problems in that layer strength of the image formation layer is low, which results in lowering of printing durability, and fogging by pressure applied to the image formation layer which is to be removed during development to form non-image portions is likely to occur at the non-image portions. In order to solve the problems as described above, there is proposal in which a water-soluble resin or a thermoplastic resin is incorporated in the image formation layer (see Patent Document 3). However, the proposal is not sufficient in printing durability in printing employing a blocking powder. Further, incorporation of resins with high melting point to the image formation layer has new problems in that it lowers on-press development properties and increases energy necessary to form an image (lowers sensitivity), which results in lowering of productivity.

### Patent Document 1:

### Japanese Patent O.P.I. Publication No. 9-123387

### Patent Document 2:

### Japanese Patent O.P.I. Publication No. 9-123388

### Patent Document 3:

### Japanese Patent O.P.I. Publication No. 2000-238451

### DISCLOSURE OF THE INVENTION

### Problems to be Solved by the Invention

The present invention has been made in view of the above. An object of the invention is to provide a planographic printing plate material that excels in on-press development property, printing durability, sensitivity and resistance to fogging by pressure, and a printing process employing the planographic printing plate material.

### Means for Solving the Above Problems

The present inventor has made an extensive study in order to solve the above-described problems. As a result, he has found that incorporation of heat melting particles having a specific composition into an image formation layer provides a planographic printing plate material that excels in printing durability in the printing employing a blocking powder and in resistance to fogging by pressure at non-image portions, without lowering sensitivity or on-press developing property.

The above object has been attained by one of the following constitutions:

1. A planographic printing plate material of on-press development type comprising a support and provided thereon, a hydrophilic layer and a thermosensitive image formation layer, wherein the thermosensitive image formation layer contains heat fusible particles in an amount of not less than 10% by weight based on the total solid content of the thermosensitive image formation layer, the heat fusible particles comprising a heat melting compound having a melting point of from 60 to 100° C. and a heat softening compound having a softening point of from 70 to 150° C.

2. The planographic printing plate material of item 1 above, wherein the content ratio (by weight) of the heat melting compound to the heat softening compound in the heat fusible particles is from 97:3 to 50:50.

3. The planographic printing plate material of item 1 above, wherein the heat fusible particles are obtained by mixing the heat melting compound with the heat softening compound, heat melting the resulting mixture, and dispersing the heat melted mixture in a dispersion medium.

4. A printing process comprising the steps of forming an image on the planographic printing plate material of any one of claims 1 through 3, employing a thermal head or a thermal laser, mounting the resulting planographic printing plate material on a printing press, and developing the resulting planographic printing plate material on the printing press by supplying dampening water or both of dampening water and printing ink to the planographic printing plate material, followed by printing.

### EFFECTS OF THE INVENTION

The present invention has been made in view of the above, and an object of the invention is to provide a planographic printing plate material providing excellent on-press development property, high printing durability, high sensitivity, and high resistance to fogging by pressure and to provide a printing process employing the planographic printing plate material.

### PREFERRED EMBODIMENTS OF THE INVENTION

The preferred embodiments of the invention will be explained below, but the invention is not limited thereto.

The present invention will be detailed below.

In the present invention, a planographic printing plate material of on-press development type, which comprises a support and provided thereon, a hydrophilic layer and a thermosensitive image formation layer, is characterized in that the thermosensitive image formation layer contains heat fusible particles comprising a heat melting compound having a melting point of from 60 to 100° C. and a heat softening compound having a softening point of from 70 to 150° C. in amount of not less than 10% by weight based on the total solid content of the thermosensitive image formation layer.

The heat melting compound is a material having a low melt viscosity, which is generally classified into wax. The material preferably has a melting point of from 60° C. to 100° C. The melting point less than 60° C. has a problem in storage stability, while the melting point exceeding 100° C. has a tendency to lower printing quality. Accordingly, the above melting point range is preferred.

The heat melting compound is preferably hard at ordinary temperature, and is preferably a compound having a penetration at 25° C. of less than 5, the penetration being defined in JIS K2207. The penetration exceeding 5 has a tendency to lower printing durability or resistance to fogging by pressure. Accordingly, the above range of the penetration is preferred.

Typical examples of the heat melting compound include carnauba wax, paraffin wax, montan wax, microcrystalline wax, candelilla wax, fatty acid type wax, fatty acid ester, fatty acid amide, and fatty acid. Of these, carnauba wax, paraffin wax, microcrystalline wax, fatty acid ester, fatty acid amide, and fatty acid are preferred. Particularly carnauba wax has a relatively low melting point and a low melt viscosity, and can form an image at high sensitivity.

In order to increase compatibility of the wax with the heat softening compound or dispersibility of the wax in a medium, wax may be oxidized or a polar group such as a hydroxyl group, an ester group, a carboxyl group, an aldehyde group and a peroxide group may be introduced into the wax.

Moreover, in order to adjust the melting temperature or melt viscosity, stearoamide, linolenamide, laurylamide, myristylamide, hardened cattle fatty acid amide, parmitylamide, oleylamide, rice bran oil fatty acid amide, palm oil fatty acid amide, a methylol compound of the above-mentioned amide compounds, methylenebisstearoamide or ethylenebisstearoamide may be added to the wax.

As the heat softening compound, one having a softening point of from 70 to 150° C. and having compatibility with the heat melting compound described above can be used.

Typical examples of the heat softening compound include polyethylene, polypropylene, ethylene-propylene copolymer, ethylene-vinyl acetate copolymer, ethylene-ethyl acrylate copolymer, ethylene-methyl acrylate copolymer, ethylene-butyl acrylate copolymer, alicyclic saturated hydrocarbon resin, rosin ester resin, and alkylphenol resin, which are preferably used. Especially preferred are polyethylene, ethylene-vinyl acetate copolymer, ethylene-ethyl acrylate copolymer, alicyclic saturated hydrocarbon resin, rosin ester resin, and alkylphenol resin.

It is preferred that the heat melting compound used in the invention has a relatively low polarity. Accordingly, it is preferred that the heat melting compound to be mixed has in the molecule at least a low polarity group having compatibility with the heat melting compound.

The heat fusible particles are prepared by a process which comprises mixing the heat melting compound with the heat softening compound in a specific proportion, heating the resulting mixture at a temperature of not less than the melting point of the heat melting compound, and dispersing the heated mixture in a dispersion medium.

In the invention, the content ratio (by weight) of the heat melting compound to the heat softening compound in the heat fusible particles is preferably from 97:3 to 50:50, and more preferably from 95:5 to 70:30. The content ratio of the heat melting compound to the heat softening compound exceeding 97 is insufficient in printing durability or resistance to fogging by pressure, while that less than 50 has a tendency to lower sensitivity or on-press developability. Therefore, the above content ratio range is preferred.

As a dispersion medium in which the heat fusible particles are dispersed, water, an organic solvent and a mixture thereof are appropriately used. In the invention, the dispersion medium contains water in an amount of preferably not less than 50% by weight, and more preferably from 80 to 100% by weight. Examples of the organic solvent include methanol, ethanol, and propanol.

A dispersant can be added to the dispersion medium, as necessary. Examples of the dispersant include a surfactant such as polyoxyethylene nonylphenyl ether, polyoxyethylene alkyl ester, polypropylene glycol-polyethylene glycol block copolymer, polyoxyethylene polyoxypropylene block copolymer, or sodium alkylbenzene sulfonate; and a water soluble resin such as polyvinyl alcohol. The dispersant content of the dispersion medium is preferably from 0.5 to 10% by weight, and more preferably from 1 to 5% by weight, based on the dispersion medium.

Alkali agents such as potassium hydroxide, morpholine, and triethanol amine can be added to the dispersion medium as a dispersion stabilizer. These can be preferably used, since they neutralize the oxidized portion of the heat melting compound or heat softening compound as described above to change to a hydrophilic group, whereby dispersibility or emulsifiability is increased.

The added amount of the alkali agents in a dispersion medium is appropriately determined depending on nature of the dispersion medium, but in the invention. The added amount of the alkali agents in a dispersion medium is preferably an amount such that the pH of the dispersion is from 7.5 to 11.

As a dispersion method employing a dispersion medium, there are known dispersion techniques, for example, a dispersion method employing media such as a ball mill, a sand mill or an atriter, and a melting and stirring dispersion method. As a method for obtaining particles with a uniform particle size is especially preferred a ball mill dispersion method in which a mixture of the heat melting compound and heat softening compound after heat melted is dispersed in a ball mill at a dispersion temperature of not more than the melting point of the heat melting compound or a melting and stirring dispersion method in which a mixture of the heat melting compound and heat softening compound after heat melted is dropwise added to a dispersion medium with stirring while controlling the temperature.

The average particle size of the heat fusible particles is preferably from 0.1 to 1.0 μm, and more preferably from 0.3 to 0.7 μm.

The heat fusible particle content of the thermosensitive image formation layer in the planographic printing plate material of the invention is not less than 10% by weight, preferably from 10 to 60% by weight, and more preferably from 15 to 50% by weight, based on the weight of the thermosensitive image formation layer. The heat fusible particle content less than 10% by weight has a tendency that function of the heat fusible particles is not sufficiently displayed, while heat fusible particle content exceeding 60% by weight has a tendency that sensitivity lowers.

As a method of determining a heat fusible particle content of the image formation layer in the invention, there are a method which controls a heat fusible particle content of an image formation layer coating solution and a method in which the image formation layer is peeled from the planographic printing plate material in the invention and a laminogram of the peeled image formation layer, which is obtained by photographing through a scanning electron microscope, is analyzed.

The thermosensitive image formation layer in the invention can contain particles of a known heat melting compound or particles of a thermoplastic compound in addition to the heat fusible particles described above, as long as function of the heat melting particles is not jeopardized.

The thermosensitive image formation layer in the invention can contain a water-soluble material. When a thermosensitive image formation layer at non-image portions is removed on a printing press by dampening water or printing ink, incorporation of the water-soluble material in the thermosensitive layer can facilitate the removal.

As the water-soluble material, a water-soluble resin can be used which is exemplified as material which can be contained in a hydrophilic layer described later. As the water-soluble resin used in the thermosensitive image formation layer in the invention, there is mentioned a water-soluble resin selected from hydrophilic natural polymers and synthetic polymers. Examples of the water-soluble resin preferably used in the invention include natural polymers such as gum arabic, water-soluble soybean polysaccharides, cellulose derivatives (for example, carboxymethylcellulose, carboxyethylcellulose, or methylcellulose) or their modification compounds, white dextrin, pullulan, or enzyme-decomposed etherified dextrin; and synthetic polymers such as polyvinyl alcohol (preferably one with a saponification degree of not less than 70 mol %), polyacrylic acid or its alkali metal or amine salt, an acrylic acid copolymer or its alkali metal or amine salt, polyacrylic acid or its alkali metal or amine salt, vinyl alcohol-acrylic acid copolymer or its alkali metal or amine salt, a homopolymer or copolymer of acryl amide, poly(hydroxyethyl acrylate), polyvinyl pyrrolidone or its copolymer, poly(vinyl methyl ether), vinyl methyl ether-maleic anhydride copolymer, or poly(2-acrylamide-2-methyl-1-propane sulfonic acid) or its alkali metal or amine salt. These resins can be used as an admixture of two or more kinds thereof, depending on the objective. However, the present invention is not limited thereto.

The water-soluble resin content of the thermosensitive image formation layer is preferably from 1 to 50% by weight, and more preferably from 2 to 10% by weight, based on the total weight of the thermosensitive image formation layer.

Image formation for the printing method of the invention can be carried out by applying heat, and is carried out preferably by infrared laser exposure. Exposure applied in the invention is preferably scanning exposure, which is carried out employing a laser which can emit light having a wavelength of infrared and/or near-infrared regions, that is, a wavelength of from 700 to 1500 nm. As the laser, a gas laser can be used, but a semi-conductor laser, which emits light having a near-infrared region wavelength, is preferably used.

A device suitable for the exposure may be any device capable of forming an image on the printing plate precursor according to image signals from a computer employing a semi-conductor laser. Generally, the following three exposure processes are mentioned. (1) A process in which a plate precursor provided on a fixed horizontal plate is scanning exposed in two dimensions, employing one or several laser beams.

(2) A process in which the surface of a plate precursor provided along the inner peripheral wall of a fixed cylinder is subjected to scanning exposure in the rotational direction (in the main scanning direction) of the cylinder, employing one or several lasers located inside the cylinder, moving the lasers in the normal direction (in the sub-scanning direction) to the rotational direction of the cylinder.

(3) A process in which the surface of a plate precursor provided along the outer peripheral wall of a fixed cylinder is subjected to scanning exposure in the rotational direction (in the main scanning direction) of the cylinder, employing one or several lasers located inside the cylinder, moving the lasers in the normal direction (in the sub-scanning direction) to the rotational direction of the cylinder.

In the invention, the process (3) above is preferable, and especially preferable when a printing plate precursor mounted on a plate cylinder of a printing press is scanning exposed.

The material used in the hydrophilic layer of the printing plate material of the invention will be explained below.

A matrix of the hydrophilic layer is preferably a metal oxide, and more preferably metal oxide particles. There are colloidal silica, an alumina sol, a titania sol and another metal oxide sol. The metal oxide particles may have any shape such as spherical, needle-like, and feather-like shape. When the metal oxide particles are spherical, the average particle diameter thereof is preferably from 3 to 100 nm, and plural kinds of metal oxide each having a different size may be used in combination. The surface of the particles may be subjected to surface treatment. The metal oxide particles can be used as a binder, utilizing its layer forming ability. The metal oxide particles are suitably used in a hydrophilic layer since they minimize lowering of the hydrophilicity of the layer as compared with an organic compound binder.

Among the above-mentioned, colloidal silica is particularly preferred. The colloidal silica has a high layer forming ability under a drying condition with a relative low temperature, and can provide a good layer strength. It is preferred that the colloidal silica used in the invention is necklace-shaped colloidal silica or colloidal silica having an average particle diameter of not more than 20 nm, and preferably from 3 to 20 nm, each being described later. Further, it is preferred that the colloidal silica provides an alkaline colloidal silica solution as a colloid solution. The colloidal silica to be used in the invention is a generic term of an aqueous dispersion system of spherical silica having a primary particle diameter of the order of nm. The necklace-shaped colloidal silica to be used in the invention means a “pearl necklace-shaped” colloidal silica formed by connecting spherical colloidal silica particles each having a primary particle diameter of from 10 to 50 μm so as to attain a length of from 50 to 400 nm. The term of “pearl necklace-shaped” means that the image of connected colloidal silica particles is like to the shape of a pearl necklace. The bonding between the silica particles forming the necklace-shaped colloidal silica is considered to be —Si—O—Si—, which is formed by dehydration of —SiOH groups located on the surface of the silica particles.

Concrete examples of the necklace-shaped colloidal silica include Snowtex-PS series produced by Nissan Kagaku Kogyo, Co., Ltd. As the products, there are Snowtex-PS-S (the average particle diameter in the connected state is approximately 110 nm), Snowtex-PS-M (the average particle diameter in the connected state is approximately 120 nm) and Snowtex-PS-L (the average particle diameter in the connected state is approximately 170 nm). Acidic colloidal silicas corresponding to each of the above-mentioned are Snowtex-PS-S-O, Snowtex-PS-M-O and Snowtex-PS-L-O, respectively.

The necklace-shaped colloidal silica is preferably used in a hydrophilic layer as a porosity providing material for hydrophilic matrix phase, and porosity and strength of the layer can be secured by its addition to the layer. Among them, the use of Snowtex-PS-S, Snowtex-PS-M or Snowtex-PS-L, each being alkaline colloidal silica particles, is particularly preferable since the strength of the hydrophilic layer is increased and occurrence of background contamination is inhibited even when a lot of prints are printed.

It is known that the binding force of the colloidal silica particles is become larger with decrease of the particle diameter. The average primary particle diameter of the colloidal silica particles to be used in the invention is preferably not more than 20 nm, and more preferably 3 to 15 nm. As above-mentioned, the alkaline colloidal silica particles show the effect of inhibiting occurrence of the background contamination. Accordingly, the use of the alkaline colloidal silica particles is particularly preferable.

Examples of the alkaline colloidal silica particles having the average primary particle diameter within the foregoing range include Snowtex-20 (10 to 20 nm), Snowtex-30 (10 to 20 nm), Snowtex-40 (10 to 20 nm), Snowtex-N (10 to 20 nm), Snowtex-S (8 to 11 nm) and Snowtex-XS (4 to 6 nm), each produced by Nissan Kagaku Co., Ltd.

The colloidal silica particles having an average primary particle diameter of not more than 20 nm, when used together with the necklace-shaped colloidal silica as described above, is particularly preferred, since appropriate porosity of the layer is maintained and the layer strength is further increased.

The ratio of the colloidal silica particles having an average primary particle diameter of not more than 20 nm to the necklace-shaped colloidal silica is preferably from 95/5 to 5/95, more preferably from 70/30 to 20/80, and most preferably from 60/40 to 30/70.

The hydrophilic layer of the printing plate material in the invention can contain porous metal oxide particles with a particle diameter of less than 1 μm as porosity providing material. Examples of the porous metal oxide particles include porous silica particles, porous aluminosilicate particles or zeolite particles as described later.

The porous silica particles are ordinarily produced by a wet method or a dry method. By the wet method, the porous silica particles can be obtained by drying and pulverizing a gel prepared by neutralizing an aqueous silicate solution, or pulverizing the precipitate formed by neutralization. By the dry method, the porous silica particles are prepared by combustion of silicon tetrachloride together with hydrogen and oxygen to precipitate silica. The porosity or particle size of these particles can be controlled by adjusting the manufacturing condition. Porous silica particles are preferably ones prepared from sol-gel in the wet method described in Claim 5.

The porous aluminosilicate particles can be prepared by the method described in, for example, JP O.P.I. No. 10-71764. Thus prepared aluminosilicate particles are amorphous complex particles synthesized by hydrolysis of aluminum alkoxide and silicon alkoxide as the major components. The particles can be synthesized so that the ratio of alumina to silica in the particles is within the range of from 1:4 to 4:1. Complex particles composed of three or more components prepared by an addition of another metal alkoxide may also be used in the invention. In such a particle, the porosity and the particle diameter can be controlled by adjustment of the production conditions. The porosity of the particles is preferably not less than 1.0 ml/g, more preferably not less than 1.2 ml/g, and most preferably of from 1.8 to 2.5 ml/g, in terms of pore volume before the dispersion. The pore volume is closely related to water retention of the coated layer. As the pore volume increases, the water retention is increased, stain is difficult to occur, and water tolerance is high. Particles having a pore volume of more than 2.5 ml/g are brittle, resulting in lowering of durability of the layer containing them. Particles having a pore volume of less than 0.5 ml/g may provide insufficient printing property.

As porosity providing material, zeolite can be used. Zeolite is a crystalline aluminosilicate, which is a porous material having voids of a regular three dimensional net work structure and having a pore size of 0.3 to 1 nm. Natural and synthetic zeolites are expressed by the following formula.

(M1,M2_{1/2})ₘ(AlₘSiₙO₂₍ₘ₊ₙ₎).xH₂O

In the above, M1 and M2 are each exchangeable cations. Examples of M1 include Li⁺, Na⁺, K⁺, Tl⁺, Me₄N⁺ (TMA), Et₄N⁺ (TEA), Pr₄N⁺ (TPA), C₇H₁₅N²⁺ and C₈H₁₆N⁺, and examples of M2 include Ca²⁺, Mg²⁺, Ba²⁺, Sr²⁺ and (C₈H₁₈N)₂²⁺. Relation of n and m is n≧m, and consequently, the ratio of m/n, or that of Al/Si is not more than 1. A higher Al/Si ratio shows a higher content of the exchangeable cation, and a higher polarity, resulting in higher hydrophilicity. The Al/Si ratio is within the range of preferably from 0.4 to 1.0, and more preferably 0.8 to 1.0. x is an integer.

Synthetic zeolite having a stable Al/Si ratio and a sharp particle diameter distribution is preferably used as the zeolite particles to be used in the invention. Examples of such zeolite include Zeolite A: Na₁₂(Al₁₂Si₁₂O₄₈).27H₂O; Al/Si=1.0, Zeolite X: Na₈₆(Al₈₆Si₁₀₆O₃₈₄).264H₂O; Al/Si=0.811, and Zeolite Y: Na₅₆(Al₅₆Si₁₃₆O₃₈₄).250H₂O; Al/Si=0.412.

Containing the porous zeolite particles having an Al/Si ratio within the range of from 0.4 to 1.0 in the hydrophilic layer greatly raises the hydrophilicity of the hydrophilic layer itself, whereby contamination in the course of printing is inhibited and the water retention latitude is also increased. Further, contamination caused by a finger mark is also greatly reduced. When Al/Si is less than 0.4, the hydrophilicity is insufficient and the above-mentioned improving effects are lowered.

The hydrophilic matrix of the printing plate material in the invention can contain layer structural clay mineral particles as a metal oxide. Examples of the layer structural clay mineral particles include a clay mineral such as kaolinite, halloysite, talk, smectite such as montmorillonite, beidellite, hectorite and saponite, vermiculite, mica and chlorite; hydrotalcite; and a layer structural polysilicate such as kanemite, makatite, ilerite, magadiite and kenyte. Among them, ones having a higher electric charge density of the unit layer are higher in the polarity and in the hydrophilicity. Preferable charge density is not less than 0.25, more preferably not less than 0.6. Examples of the layer structural mineral particles having such a charge density include smectite having a negative charge density of from 0.25 to 0.6 and bermiculite having a negative charge density of from 0.6 to 0.9. Synthesized fluorinated mica is preferable since one having a stable quality, such as the particle diameter, is available. Among the synthesized fluorinated mica, swellable one is preferable and one freely swellable is more preferable.

An intercalation compound of the foregoing layer structural mineral particles such as a pillared crystal, or one treated by an ion exchange treatment or a surface treatment such as a silane coupling treatment or a complication treatment with an organic binder is also usable.

The planar structural mineral particles are preferably in the plate form, and have an average particle diameter (an average of the largest particle length) of less than 1 μm, and an average aspect ratio (the largest particle length/the particle thickness) of preferably not less than 50, in a state contained in the layer including the case that the particles are subjected to a swelling process and a dispersing layer-separation process. When the particle diameter is within the foregoing range, continuity to the parallel direction, which is a trait of the layer structural particle, and softness, are given to the coated layer so that a strong dry layer in which a crack is difficult to be formed can be obtained. The coating solution containing the layer structural clay mineral particles in a large amount can minimize particle sedimentation due to a viscosity increasing effect. The particle diameter falling outside the above range may produce non-uniformity in the coated layer, resulting in lowering strength of the layer. The aspect ratio less than the lower limit of the above range reduces the number of the particles relative to the addition amount, and lowers viscosity increasing effect, resulting in lowering of particle sedimentation resistance.

The content of the layer structural clay mineral particles is preferably from 0.1 to 30% by weight, and more preferably from 1 to 10% by weight based on the total weight of the layer. Particularly, the addition of the swellable synthesized fluorinated mica or smectite is effective if the adding amount is small. The layer structural clay mineral particles may be added in the form of powder to a coating liquid, but it is preferred that gel of the particles which is obtained by being swelled in water, is added to the coating liquid in order to obtain a good dispersity according to an easy coating liquid preparation method which requires no dispersion process comprising dispersion due to media.

In the invention, the following materials can be added to the hydrophilic layer in the invention, as long as they lower the properties of the invention.

An aqueous solution of a silicate is usable. An alkali metal silicate such as sodium silicate, potassium silicate or lithium silicate is preferable, and the ratio SiO₂/M₂O is preferably selected so that the pH value of the coating liquid after addition of the silicate does not exceed 13 in order to prevent dissolution of the porous metal oxide particles or the colloidal silica particles.

An inorganic polymer prepared by a sol-gel method employing a metal alkoxide or an inorganic-organic hybrid polymer can be used. Known methods described in S. Sakka “Application of Sol-Gel Method” or in the publications cited in the above publication can be applied to preparation of the inorganic polymer by the sol-gel method or of the inorganic-organic hybrid polymer.

The hydrophilic layer may contain a water soluble resin. Examples of the water soluble resin include polysaccharides, polyethylene oxide, polypropylene oxide, polyvinyl alcohol, polyethylene glycol (PEG), polyvinyl ether, a styrene-butadiene copolymer, a conjugation diene polymer latex of methyl methacrylate-butadiene copolymer, an acryl polymer latex, a vinyl polymer latex, polyacrylamide, and polyvinyl pyrrolidone. In the invention, polysaccharides are preferred. As the polysaccharide, starches, celluloses, polyuronic acid and pullulan can be used. Among them, a cellulose derivative such as a methyl cellulose salt, a carboxymethyl cellulose salt or a hydroxyethyl cellulose salt is preferable, and a sodium or ammonium salt of carboxymethyl cellulose is more preferable. These polysaccharides can form a preferred surface shape of the hydrophilic layer.

The surface of the hydrophilic layer preferably has a convexoconcave structure having a pitch of from 0.1 to 20 μm such as the grained aluminum surface of an aluminum PS plate. The water retention ability and the image maintaining ability are raised by such a convexoconcave structure of the surface. Such a convexoconcave structure can also be formed by adding in an appropriate amount a filler having a suitable particle diameter to the coating liquid of the hydrophilic layer. However, the convexoconcave structure is preferably formed by coating a coating liquid for the hydrophilic layer containing the alkaline colloidal silica and the water-soluble polysaccharide so that the phase separation occurs at the time of drying the coated liquid, whereby a structure is obtained which provides a good printing performance.

The shape of the convexoconcave structure such as the pitch and the surface roughness thereof can be suitably controlled by the kinds and the adding amount of the alkaline colloidal silica particles, the kinds and the adding amount of the water-soluble polysaccharide, the kinds and the adding amount of another additive, a solid concentration of the coating liquid, a wet layer thickness or a drying condition.

It is preferred that the water soluble resin is contained in the hydrophilic layer in such a state that at least a part of the water soluble resin is capable of being dissolved in water. This is because even the water soluble resin, when cross-linked with a cross-linking agent, is water insoluble, which lowers its hydrophilicity and printing properties.

A cationic resin may also be contained in the hydrophilic layer. Examples of the cationic resin include a polyalkylene-polyamine such as a polyethyleneamine or polypropylenepolyamine or its derivative, an acryl resin having a tertiary amino group or a quaternary ammonium group and diacrylamine. The cationic resin may be added in a form of fine particles. Examples of such particles include the cationic microgel described in Japanese Patent O.P.I. Publication No. 6-161101.

A water-soluble surfactant may be added for improving the coating ability of the coating liquid for the hydrophilic layer in the invention. A silicon atom-containing surfactant and a fluorine atom-containing surfactant are preferably used. The silicon atom-containing surfactant is especially preferred in that it minimizes printing contamination. The content of the surfactant is preferably from 0.01 to 3% by weight, and more preferably from 0.03 to 1% by weight based on the total weight of the hydrophilic layer (or the solid content of the coating liquid).

The hydrophilic layer in the invention can contain a phosphate. Since a coating liquid for the hydrophilic layer is preferably alkaline, the phosphate to be added to the hydrophilic layer is preferably sodium phosphate or sodium monohydrogen phosphate. The addition of the phosphate provides improved reproduction of dots at shadow portions. The content of the phosphate is preferably from 0.1 to 5% by weight, and more preferably from 0.5 to 2% by weight in terms of amount excluding hydrated water.

The hydrophilic layer can contain a light-to-heat conversion material described later. The light-to-heat conversion material, when particles, is preferably ones with a particle diameter of less than 1 μm. In the invention, the hydrophilic layer preferably contains inorganic particles with a particle size of not less than 1 μm or particles covered with inorganic materials.

Any of a porous substance, a non-porous substance, organic resin particles or inorganic particles can be used. Examples of the inorganic fillers include silica, alumina, zirconia, titania, carbon black, graphite, TiO₂, BaSO₄, ZnS, MgCO₃, CaCO₃, ZnO, CaO, WS₂, MoS₂, MgO, SnO₂, Al₂O₃, α-Fe₂O₃, α-FeOOH, SiC, CeO₂, BN, SiN, MoC, BC, WC, titanium carbide, corundum, artificial diamond, garnet, garnet, quartz, silica rock, tripoli, diatomite, and dolomite. Examples of the organic fillers include polyethylene fine particles, fluororesin particles, guanamine resin particles, acrylic resin particles, silicone resin particles, melamine resin particles, and the like. As the inorganic material coated fillers, there are, for example, particles in which organic particles such as particles of PMMA or polystyrene as core particles are coated with inorganic particles with a particle diameter smaller that that of the core particles. The particle diameter of the inorganic particles is preferably from 1/10 to 1/100 of that of the core particles. As the inorganic particles, particles of known metal oxides such silica, alumina, titania and zirconia can be used. Various coating methods can be used, but a dry process is preferred which core particles collide with particles for coating at high speed in air as in a hybridizer to push the particles for coating in the core particle surface and fix, whereby the core particles are coated with the particles for coating.

Particles, in which the organic core particles are plated with metal, can be used. As such particles, there is, for example, “Micropearl AU”, produced by SEKISUI KAGAKU KOGYO Co, Ltd., in which resin particles are plated with gold.

Particularly in order to minimize particle sedimentation in a coating liquid, porous inorganic fillers such as porous silica particles or porous aluminosilicate particles, or fillers covered with porous inorganic particles are preferably used. The particle diameter of the fillers is preferably from 1 to 12 μm, more preferably from 1.5 to 8 μm, and still more preferably from 2 to 6 μm. The particles diameter exceeding 12 μm results in problem of lowering dissolution of formed images or contaminating a blanket. The particles described above with a particle diameter of not less than 1 μm are contained in the hydrophilic layer in an amount of preferably from 1 to 50% by weight, and more preferably from 5 to 40% by weight.

In the hydrophilic layer, the content of carbon-containing materials such as organic resins or carbon black is preferably low in increasing hydrophilicity. The content of the carbon-containing materials in the hydrophilic layer is preferably less than 9% by weight, and more preferably less than 5% by weight.

The hydrophilic layer may be plural, and an under hydrophilic layer may be provided under the hydrophilic layer described above. When the under layer is provided, materials used in the under layer include the same materials as in the hydrophilic layer described above. The under layer, when it is porous, is less advantageous. Since the under layer is preferably non-porous in view of strength of the layer, the porosity providing agent content of the under layer is preferably lower than that of the hydrophilic layer. It is more preferable that the under layer contains no porosity providing agent. The content of the particles having a particle diameter of not less than 1 μm described above in the under layer is preferably from 1 to 50% by weight, and more preferably from 5 to 40% by weight. Like the hydrophilic layer, the content of carbon-containing materials such as the organic resins or carbon black in the under layer is preferably lower in increasing hydrophilicity of the under layer. The total content of these materials in the under layer is preferably less than 9% by weight, and more preferably less than 5% by weight.

In the invention, at least one of the hydrophilic layer, under layer and image formation layer preferably contain a light-to-heat conversion material described later, whereby high sensitivity is realized.

In the invention, the hydrophilic layer can contain the following metal oxides as the light-to-heat conversion material. Materials having black color in the visible regions or materials, which are electro-conductive or semi-conductive, can be used.

Examples of the former include black iron oxide (Fe₃O₄) and black complex metal oxides containing at least two metals.

Examples of the latter include Sb-doped SnO₂ (ATO), Sn-added In₂O₃ (ITO), TiO₂, TiO prepared by reducing TiO₂ (titanium oxide nitride, generally titanium black). Particles prepared by covering a core material such as BaSO₄, TiO₂, 9Al₂O₃.2B₂O and K₂O.nTiO₂ with these metal oxides is usable. These oxides are particles having a particle diameter of not more than 0.5 μm, preferably not more than 100 nm, and more preferably not more than 50 nm.

As these light-to-heat conversion materials, black complex metal oxides containing at least two metals are more preferred.

Examples of the black complex metal oxides include black complex metal oxides comprising at least two selected from Al, Ti, Cr, Mn, Fe, Co, Ni, Cu, Zn, Sb, and Ba. These can be prepared according to the methods disclosed in Japanese Patent O.P.I. Publication Nos. 9-27393, 9-25126, 9-237570, 9-241529 and 10-231441.

The black complex metal oxide used in the invention is preferably a complex Cu—Cr—Mn type metal oxide or a Cu—Fe—Mn type metal oxide. The Cu—Cr—Mn type metal oxides are preferably subjected to the treatment disclosed in Japanese Patent O.P.I. Publication Nos. 8-27393 in order to reduce isolation of a 6-valent chromium ion. These complex metal oxides have a high color density and a high light heat conversion efficiency as compared with another metal oxide.

The primary average particle diameter of these black complex metal oxides is preferably from 0.001 to 1.0 μm, and more preferably from 0.01 to 0.5 μm. The primary average particle diameter of from 0.001 to 1.0 μm improves a light heat conversion efficiency relative to the addition amount of the particles, and the primary average particle diameter of from 0.05 to 0.5 μm further improves a light heat conversion efficiency relative to the addition amount of the particles. The light heat conversion efficiency relative to the addition amount of the particles depends on a dispersity of the particles, and the well-dispersed particles have a high light heat conversion efficiency. Accordingly, these black complex metal oxide particles are preferably dispersed according to a known dispersing method, separately to a dispersion liquid (paste), before being added to a coating liquid for the particle containing layer. The metal oxides having a primary average particle diameter of less than 0.001 are not preferred since they are difficult to disperse. A dispersant is optionally used for dispersion. The addition amount of the dispersant is preferably from 0.01 to 5% by weight, and more preferably from 0.1 to 2% by weight, based on the weight of the black complex metal oxide particles.

The content of the black complex metal oxide in the hydrophilic layer is preferably from 20% by weight to less than 40% by weight, more preferably from 25% by weight to less than 39% by weight, and still more preferably from 25% by weight to less than 30% by weight, based on the total solid amount of hydrophilic layer. The content less than 20% by weight of the oxide provides poor sensitivity, while the content not less than 40% by weight of the oxide produces ablation scum due to ablation.

The hydrophilic layer or image formation layer in the invention can contain the following infrared absorbing dye as a light-to-heat conversion material.

Examples of the infrared absorbing dye include a general infrared absorbing dye such as a cyanine dye, a chloconium dye, a polymethine dye, an azulenium dye, a squalenium dye, a thiopyrylium dye, a naphthoquinone dye or an anthraquinone dye, and an organometallic complex such as a phthalocyanine compound, a naphthalocyanine compound, an azo compound, a thioamide compound, a dithiol compound or an indoaniline compound. Exemplarily, the light-to-heat conversion materials include compounds disclosed in Japanese Patent O.P.I. Publication Nos. 63-139191, 64-33547, 1-160683, 1-280750, 1-293342, 2-2074, 3-26593, 3-30991, 3-34891, 3-36093, 3-36094, 3-36095, 3-42281, 3-97589 and 3-103476. These compounds may be used singly or in combination. The content of the infrared absorbing dye in the image formation layer is preferably from 0.1% by weight to less than 10% by weight, more preferably from 0.3% by weight to less than 7% by weight, and still more preferably from 0.5% by weight to less than 6% by weight, based on the total solid amount of hydrophilic layer. As is described above, the content less than 0.1% by weight of the oxide provides poor sensitivity, while the content not less than 10% by weight of the oxide produces ablation scum due to ablation. Therefore, the above-described range is preferred.

In the printing plate material of the invention, it is preferred that at least one back coat layer is provided on the surface of the support opposite the image formation layer, in order to improve handling properties and minimize change in physical properties during storage. The back coat layer preferably contains a hydrophilic binder. When the support surface is hydrophobic, it may be a layer containing a water dispersible resin (polymer latex) disclosed in paragraphs (00339 through (0038) of Japanese Patent O.P.I. Publication Nos. 2002-258469.

The hydrophilic binder may be any as long as it exhibits hydrophilicity, and examples of the hydrophilic binder include resins having, as a hydrophilic group, a hydroxyl group such as polyvinyl alcohol (PVA), cellulose resins (methylcellulose MC, ethylcellulose EC, hydroxyethylcellulose HEC, carboxymethylcellulose CMC), chitins, or starch; resins having an ether bond such as polyethylene oxide PEO, polypropylene oxide PPO, polyethylene glycol PEG, or polyvinyl ether PVE; resins having an amide group or an amide bond such as polyacryl amide PAAM or polyvinyl pyrrolidone PVP; resins having as a dissociation group a carboxyl group such as polyacrylic acid salts, maleic acid resins, alginates or gelatins; polystyrene sulfonic acid salt; resins having an amino group, an imino group, a tertiary amino group or a quaternary ammonium group such as polyallylamine PAA, polyethylene imine PEI, epoxidated polyamide EPAM, polyvinyl pyridine or gelatins.

The hydrophobic binder may be any as long as it exhibits hydrophobicity, and examples of the hydrophobic binder include polymers derived from α,β-ethylenically unsaturated monomers such as polyvinyl chloride, chlorinated polyvinyl chloride, a copolymer of vinyl chloride and vinylidene chloride, a copolymer of vinyl chloride, and vinyl acetate, polyvinyl acetate, partially saponified polyvinyl acetate, polyvinyl acetal or preferably polyvinyl butyral in which a part of polyvinyl alcohol is acetalized with aldehyde, a copolymer of acrylonitrile and acryl amide, polyacrylates, polymethacrylates, polystyrene, polyethylene and a mixture thereof.

It is preferred that the back coat layer contains a matting agent, in order to easily mount the printing plate on a printing press and to prevent “out of color registration” due to “out of registration” of the printing plate during printing. As the matting agent, a porous or non-porous matting agent or an organic or inorganic matting agent can be used. Examples of the inorganic matting agent include silica, alumina, zirconia; titania, carbon black, graphite, TiO₂, BaSO₄, ZnS, MgCO₃, CaCO₃, ZnO, CaO, WS₂, MoS₂, MgO, SnO₂, Al₂O₃, α-Fe₂O₃, α-FeOOH, SiC, CeO₂, BN, SiN, MoC, BC, WC, titanium carbide, corundum, artificial diamond, garnet, garnet, quartz, silica rock, tripoli, diatomite, and dolomite. Examples of the organic matting agent include polyethylene fine particles, fluororesin particles, guanamine resin particles, acrylic resin particles, silicone resin particles, melamine resin particles, and the like. As the inorganic material coated matting agents, there are, for example, particles in which organic particles such as particles of PMMA or polystyrene as core particles are coated with inorganic particles with a particle diameter smaller that that of the core particles. The particle diameter of the inorganic particles is preferably from 1/10 to 1/100 of that of the core particles. As the inorganic particles, particles of known metal oxides such silica, alumina, titania and zirconia can be used. Various coating methods can be used, but a dry process is preferred which core particles collide with particles for coating at high speed in air as in a hybridizer to push the particles for coating in the core particle surface and fix, whereby the core particles are coated with the particles for coating.

In the invention, any matting agent can be used without special limitations. Particularly when the planographic printing plate material is in the form of roll, the matting agent in the back coat layer is preferably organic resin particles in minimizing scratches on the image formation layer surface.

The average particle diameter of the matting agent is determined in terms of an average diameter of circles having the same area as projected images of the particles photographed by means of an electron microscope.

The particle diameter of the matting agent is preferably from 1 to 12 μm, more preferably from 1.5 to 8 μm, and still more preferably from 2 to 7 μm. The particle diameter exceeding 12 μm is likely to produce scratches on the image formation layer surface, while the particle diameter less than 1 μm is likely to causes floating of a planographic printing plate material from a plate cylinder.

The matting agent content of the back coat layer is preferably from 0.2 to 30% by weight, and more preferably from 1 to 10% by weight, based on the total weight of the back coat layer.

A laser recording apparatus or a processless printing press has a sensor for controlling transportation of the printing plate material. In the invention, in order to carry out the controlling smoothly, the structural layer preferably contains dyes or pigment. The dyes or pigment are preferably infrared absorbing dyes or pigment as described above used as a light-to-heat conversion material. The structural layer can further contain a surfactant.

The support of the planographic printing plate material of the invention is preferably a plastic film. Examples of the plastic include polyethylene terephthalate (PET), polyethylene naphthalate (PEN), polyimide, polyamide, polycarbonate, polysulfone, polyesters, e.g., PET or PEN is preferred, and PET is more preferred, in view of handling properties.

PET is composed of terephthalic acid and ethylene glycol, and PEN is also composed of naphthalene dicarboxylic acid and ethylene glycol. These are combined via polycondensation under the appropriate reaction condition employing a catalyst. In this case, one or more kinds of a third component may be appropriately mixed. The third component may be a compound capable having a divalent ester-forming group. Examples of a dicarboxylic acid will be shown below.

As the dicarboxylic acid, there are, for example, isophthalic acid, phthalic acid, 2,6-naphthalene dicarboxylic acid, a polymer having polylactic acid as a main component, 2,7-naphthalene dicarboxylic acid, diphenylsulfone dicarboxylic acid, diphenylether dicarboxylic acid, diphenylethane dicarboxylic acid, cyclohexane dicarboxylic acid, diphenyl dicarboxylic acid, diphenylthioether dicarboxylic acid, diphenylketone dicarboxylic acid, and diphenylindane dicarboxylic acid.

As a glycol, there are, for example, ethylene grycol, propylene glycol, tetramethylene glycol, cyclohexanedimethanol, 2,2-bis(4-hydroxyphenyl)propane, 2,2-bis(4-hydroxyethoxyphenyl)propane, bis(4-hydroxyphenyl)sulfone, bisphenolfluorene dihydroxyethyl ether, diethylene glycol, neopentylene glycol, hydroquinone, and cyclohexane diol.

The intrinsic viscosity of PET resin or film used in the present invention is preferably 0.5 to 0.8. Those having different viscosity may be used in combination.

A synthesis method of PET is not specifically limited, and PET can be manufactured according to a conventional manufacturing method. As the manufacturing method, there is a direct esterification method in which a dicarboxylic acid component is directly reacted with a diol component, or an ester exchange method in which dialkylester is first employed as dicarboxylic acid, and this one and the diol component are polymerized via the ester exchange reaction by heat application to be esterified while removing the extra diol under reduced pressure. In this case, an ester exchange catalyst, a polymerization catalyst or a heat-resistant stabilizer can be added. Examples of the heat stabilizer include phosphoric acid, phosphorous acid, and ester compounds thereof. During synthesis, an anti-stain agent, a crystal nucleus agent, a slipping agent, a stabilizer, an anti-blocking agent, a UV absorber, a viscosity adjusting agent, a transparentizing agent, an anti-static agent, a pH adjusting agent, a dye or pigment may be added.

Next, a manufacturing method of the plastic support will be explained.

A method of preparing an unstretched sheet and a sheet which is uniaxially stretched in the longitudinal direction can be a commonly known method. Polyester as a raw material is molded in the form of pellets, and after a hot-air drying process or a vacuum drying, they are melted and extruded in the form of sheets by a T-shaped die. Subsequently, they are attached firmly onto a cooling drum and cooled rapidly to obtain an unstretched sheet. Next, the resulting unstretched sheet is heated in the range of from the glass transition temperature (Tg) to Tg+100° C. via plural rollers and/or heating apparatuses such as an infrared heater and the like to be stretched in the longitudinal direction. The stretching magnification is usually 2.5 to 6.

In this case, a roll-set curl can be avoided by arranging a stretching temperature difference between both surfaces of a support. Specifically, temperature can be controlled by providing a heating apparatus such as an infrared heater or such on one surface side during heating while stretching in the longitudinal direction. The temperature difference at the time of stretching is preferably 0 to 40° C., and more preferably 0 to 20° C. In the case of the temperature difference exceeding 40° C., it is not preferable that film sheet flatness is degraded because of uneven stretching.

Next, the resulting polyester film sheet which is uniaxially stretched in the longitudinal direction is stretched in the transverse direction in the temperature range of from Tg to Tg+120° C., and subsequently fixed by heat. The transverse stretching magnification is usually 3 to 6, and the ratio of longitudinal and transverse stretching magnifications is appropriately adjusted so as to have a preferable property via measuring of properties of the resulting biaxially stretching film sheet. As to heat fixation, a heat fixation process is usually conducted in the temperature range of not more than Tg+180° C., which is higher than the final transverse stretching temperature, for 0.5 to 300 sec. In this case, film sheets are preferably heat fixed with two or more temperatures. Dimension stability of the film sheets heat fixed with such the two or more temperatures is improved, whereby a support can usefully be provided for the printing plate material.

The support for the printing plate material in the present invention is preferably subjected to relaxation treatment in view of dimension stability. The relaxation treatment can preferably be conducted before a roll-up process in a tenter for stretching in the transverse direction or in the exterior of the tenter after heat fixing in the stretching process of the foregoing polyester film sheet. The relaxation treatment is preferably carried out in a temperature of 80 to 200° C., and more preferably 100 to 180° C. The relaxation treatment is also carried out preferably in a rate of 0.1 to 10% in both longitudinal and transverse directions, and more preferably in a rate of 2 to 6%.

Particles having a size of 0.01 to 10 μm are preferably incorporated in an amount of 1 to 1000 ppm into the above support, in improving handling property. Herein, the particles may be organic or inorganic material. Examples of the inorganic material include silica described in Swiss Patent 330,158, glass powder described in French Patent 296,995, and carbonate salts of alkaline earth metals, cadmium or zinc described in British Patent 1,173,181. Examples of the organic material include starch described in U.S. Pat. No. 2,322,037, starch derivatives described such as in Belgian Patent 625,451 and British Patent 981,198, polyvinyl alcohol described in JP-B 44-3643, polystyrene or polymethacrylate described in Swiss Patent 330,158, polyacrylonitrile described in U.S. Pat. No. 3,079,257 and polycarbonate described in U.S. Pat. No. 3,022,169. The shape of the particles may be in a regular form or irregular form.

The plastic support in the present invention has a coefficient of elasticity of preferably 300 to 800 kg/mm², and more preferably 400 to 600 kg/mm², in view of the above handling property. The coefficient of elasticity herein referred to is a slope of the straight line portion in the stress-strain diagram showing the relationship between strain and stress, which is obtained employing a tension test meter according to JIS C2318. This slope is called Young's modulus, which is defined in the invention as coefficient of elasticity.

It is preferred that the support in the invention has an average thickness of from 100 to 500 μm, and a thickness distribution of not more than 5%, in that a handling property is improved when the planographic printing plate material is mounted on a press. The average thickness of the support in the invention is preferably from 120 to 300 μm, and the thickness dispersion of the support in the invention is preferably not more than 2%. The thickness dispersion herein referred to means a value (%) obtained by dividing the difference between the maximum thickness and the minimum thickness by the average thickness and then multiplying the difference by 100. The thickness dispersion of the support is determined according to the following: lines are formed at an interval of 10 cm in both the transverse and longitudinal directions on a 60 cm square support to form 36 small squares. The thickness of the 36 small squares is measured, and the average thickness, maximum thickness and minimum thickness are obtained therefrom.

The support may be subjected to heat treatment to reduce the roll-set curl. Provided as the heat treating method are a method in which heat treatment is carried out before and after rolling up in the form of roll after coating and drying each component layer of the printing plate material, and a method in which heat treatment is carried out by using a transport line while coating and drying each component layer of the printing plate material.

As a method of heat treatment in the form of roll, there is a method in which heat treatment is carried out at a temperature below the glass transition temperature for 0.1 to 1500 hours after preparing a polyester support, as described in Japanese Patent O.P.I. Publication No. 51-16358. In this case, it is preferred to conduct processes such as a process of embossing at the film edge and center portion partially or over the entire length of the film sheet, a process of bending at the edge, and a process of increasing the film thickness partially in view of a film-to-film anti-blocking. It is preferable that the polyester support has such strength that no film rolling deflection occurs, and is material quality and structure capable of being resistant to the heat treating temperature in order to avoid deformation caused by the roll core transfer.

As for a method of heat treatment by using a transport line, the roll-set curl can be minimized by heat treating while transporting a zone having a temperature slope between a glass transition temperature and not less than the glass transition temperature, as described in Japanese Patent O.P.I. Publication No. 10-39448. Though the heat treatment is carried out preferably for a longer period of time, it is preferably carried out while transporting at a CS (coating speed) of 5 to 50 m/min in view of productivity as well as transportability. Transport tension is not particularly specified, but a transport tension of 5 to 60 kg/m is preferred. In the case of heat treatment via avoiding the above-mentioned range of CS and transport, tension, it is not preferred that roll wrinkles are generated, and support surface flatness is degraded. When heat treating in the line transport, provided are a transport method in which a film sheet is transported while holding the film sheet in a state of surface flatness, a transport method employing a pin or a clip, air transport method, a roller transport method, and so forth. Of these, air transport method and a roller transport method are preferably used, and a roller transport method is more preferably used.

A plastic film support is employed as a support in the present invention, but a composite material support in which plastic film sheets are appropriately laminated with metal plates (iron, stainless steel, aluminum, an the like, for example) or paper sheet material covered by polyethylene (referred to as composite material) can be used. This composite material may be laminated prior to or after forming a coated layer, and also right before mounting on a printing press.

It is preferred in the present invention that a subbing layer is formed between a plastic support and a hydrophilic layer. The subbing layer is preferably composed of two layers. It is preferable that material adhering to the plastic support is employed on the plastic support side (lower subbing layer), and material adhering to the hydrophilic layer is also used on the hydrophilic layer side.

Examples of the material employed as a lower subbing layer include vinyl polymer, polyester, styrene, or styrene-diolefin. Vinyl polymer and polyester are particularly preferable, or it is preferred that these are used in combination or in modification.

On the other hand, material employed as an upper subbing layer is preferably a water-soluble polymer in view of improved adhesion to the hydrophilic layer, and more preferably gelatin or a water-soluble polymer having a polyvinyl alcohol unit as a main component. It is preferable that the above-mentioned water-soluble polymer is mixed with the material used in the lower subbing layer in view of adhesion of the upper subbing layer to the lower subbing layer as well as to the hydrophilic layer.

In the invention, the hydrophilic layer preferably contains a water-soluble polymer having a vinyl alcohol unit as a main component (polyvinyl alcohol type polymer). Incorporation of the water-soluble polymer having a vinyl alcohol unit as a main component into both hydrophilic layer and upper subbing layer not only improves adhesion between the plastic support and the hydrophilic layer but also provides a planographic printing plate material with excellent on-press developability and high printing durability.

Materials used in the subbing layer will be explained below.

### (Polyester)

A substantively linear polyester obtained via a polycondensation reaction of either polybasic acid or its ester, and either polyol or its ester, is used as polyester. Further in the case of being used in the water-soluble form, employed is polyester into which an example of a component having a hydrophilic group including a sulfonate-containing component, a diethylene glycol component, a polyalkylene ether glycol component, or a polyether dicarboxylic acid component is introduced as a copolymerization component. Sulfonate-containing dicarboxylic acid (dicarboxylic acid is hereinafter also referred to as polybasic acid) is preferably employed as a component having a hydrophilic group.

Examples employed as a polyester polybasic acid component include terephthalic acid, isophthalic acid, phthalic acid, phthalic anhydride, 2,6-naphthalene dicarboxylic acid, 1,4-cyclohexane dicarboxylic acid, adipic acid, sebacic acid, trimellitic acid, pyromellitic acid, dimer acid, maleic acid, fumaric acid, itaconic acid, p-hydroxybenzoic acid, and p-(β-hydroxy ethoxy) benzoic acid. A component having sulfonic-acid alkaline metal salt is preferably used as the above sulfonate-containing dicarboxylic acid. Alkaline metal salt of 4-sulfoisophthalic acid, 5-sulfoisophthalic acid, sulfoterephthalic acid, 4-sulfophthalic acid, 4-sulfonaphthalene-2,7-dicarboxylic acid, and 5-(4-sulfophenoxy) isophthalic acid are provided as examples. Of these, 5-sulfoisophthalic acid sodium salt is especially preferred. It is preferred from the aspect of water solubility and water resistance that the content of the dicarboxylic acid having a sulfonate is 5 to 15 mol %, based on the total dicarboxylic acid component, but is more preferably 6 to 10 mol %. A major dicarboxylic acid component having terephthalic acid and isophthalic acid is preferably used as water-soluble polyester, and it is further especially preferred, from the aspect of coatability and water solubility of a polyester support, that the content ratio of terephthalic acid and isophthalic acid is 30/70 to 70/30 in mol %. The content of these terephthalic acid and isophthalic acid components is preferably 50 to 80 mol %, based on the total dicarboxylic acid component, and it is further preferred that an alicyclic dicarboxylic acid is employed as a copolymerization component. Examples provided as the alicyclic dicarboxylic acid include 1,4-cyclohexane dicarboxylic acid, 1,3-cyclohexane dicarboxylic acid, 1,2-cyclohexane dicarboxylic acid, 1,3-cyclopentane dicarboxylic acid, and 4,4′-bicyclohexyl dicarboxylic acid. Dicarboxylic acid other than the above dicarboxylic acids can also be used as a copolymerization component in the water-soluble polyester containing terephthalic acid and isophthalic acid as the main dicarboxylic acid component. Examples thereof include aromatic dicarboxylic acid and straight-chained aliphatic dicarboxylic acid. The aromatic dicarboxylic acid is preferably used in the range of not more than 30 mol %, based on the total dicarboxylic acid component. Examples provided as the aromatic dicarboxylic acid include phthalic acid, 2,5-dimethyl terephthalic acid, 2,6-naphthalene dicarboxylic acid, 1,4-naphthalene dicarboxylic acid, and biphenyl dicarboxylic acid. Straight-chained aliphatic dicarboxylic acid is preferably used in the range of not more than 15 mol %, based on the total dicarboxylic acid component. Examples provided as the straight-chained aliphatic dicarboxylic acid include adipic acid, pimelic acid, suberic acid, azelaic acid, and sebacic acid.

Examples employed also as a polyol component include ethylene glycol, diethylene glycol, 1,4-butanediol, neopentylglycol, dipropylene glycol, 1,6-hexanediol, 1,4-cyclohexanedimethanol, xylylene glycol, trimethylolpropane, poly(ethylene oxide) glycol, and poly(tetramethylene oxide) glycol.

Ethylene glycol, in the range not less than 50 mol %, is preferably used as a glycol component of the water-soluble polyester, based on the total glycol component.

Polyester can be synthesized, employing either dicarboxylic acid or its ester, and either glycol or its ester, as the starting raw material, for which various methods can be employed to synthesize it. An initial condensed material of dicarboxylic acid and glycol, for example, is formed by an ester exchange method or a direct esterification method, and further the polyester resin can be acquired by a commonly known manufacturing method via melt-polymerization of the initial condensation material. As more specific examples, provided are methods such as a method of conducting a polycondensation process under high vacuum by decreasing pressure gradually after ester exchange reaction is conducted with ester of dicarboxylic acid which is, for example, dimethylester of dicarboxylic acid, and glycol, whereby methanol is distilled, a method of conducting a polycondensation process under high vacuum by gradually decreasing pressure after esterification reaction is conducted with dicarboxylic acid and glycol, whereby produced water is distilled, and also a method of conducting a polycondensation process under high vacuum after conducting esterification reaction by adding dicarboxylic acid. A commonly known catalyst can be employed as an ester exchange catalyst or a polycondensation catalyst. Examples used as the ester exchange catalyst include manganese acetate, calcium acetate, and zinc acetate. Examples used as the polycondensation catalyst include antimony trioxide, germanium oxide, dibutyltin oxide, and titanium tetrabutoxide. Various conditions of processes and components including polymerization and catalyst, however, are not limited to the above examples.

### (Vinyl Polymer)

As the vinyl polymers used in the invention, there are, for example, an alkyl acrylate or alkyl methacrylate (examples of the alkyl include methyl, ethyl, n-propyl, isopropyl, n-butyl, isobutyl, t-butyl, 2-ethylhexyl, cyclohexyl, phenyl, benzyl or phenethyl); a hydroxyl group-containing monomer such as 2-hydroxyethyl acrylate, 2-hydroxyethyl methacrylate, 2-hydroxypropyl acrylate, or 2-hydroxypropyl methacrylate; an amido group-containing monomer such as acryl amide, methacryl amide, N-methylmethacryl amide, N-methylacryl amide, N-methylolacryl amide, N-methylolmethacryl amide, N,N-dimethylolacryl amide, N-methoxymethylacryl amide, N-methoxymethylmethacryl amide, or N-phenylacryl amide; an amino group-containing monomer such as N,N-diethylaminoethyl acrylate or N,N-diethylaminoethyl methacrylate; an epoxy group-containing monomer such as glycidyl acrylate or glycidyl methacrylate; and a carboxyl or its salt group-containing monomer such as acrylic or methacrylic acid or their salt (sodium, potassium or ammonium salt). As monomers other than other than the acrylic monomers, there are, for example, an epoxy group-containing monomer such as allyl glycidyl ether; a sulfo or its salt group-containing monomer such as styrene sulfonic acid, vinyl sulfonic acid or their salt (sodium, potassium or ammonium salt), a carboxyl or its salt group-containing monomer such as crotonic acid, itaconic acid, maleic acid, fumaric acid or their salt (sodium, potassium or ammonium salt); an anhydride monomer such as maleic anhydride or itaconic anhydride; vinyl isocyanate; allyl isocyanate; styrene; vinyltrisalkoxysilane; alkylmaleic acid monoester; alkylfumaric acid monoester; acrylonitrile; methacrylonitrile; alkylitaconic acid monoester; vinylidene chloride; vinyl acetate; and vinyl chloride. As the vinyl monomers used, an epoxy group-containing monomer such as glycidyl acrylate or glycidyl methacrylate is preferred.

The acryl resin preferably used in the invention is preferably in the form of polymer latex in view of environmental protection. Herein, the polymer latex is a water-insoluble polymer, which is dispersed in water or an aqueous dispersion medium in the form of particles. The polymer latex may be one in which a polymer is emulsified in a dispersion medium, one obtained by emulsion polymerization, one in which a polymer is dispersed in the form of micelles or one in which a polymer partially having a hydrophilic structure is molecularly dispersed. Polymer latexes are described in “Synthetic Resin Emulsion” (edited by T. Okuda and H. Inagaki, published by KOBUNSHI-KANKOKAI, 1978), “Application of Synthetic Latex” (edited by Sugimura et al., published by KOBUNSHI-KANKOKAI, 1993), and “Chemistry of Synthetic Latex” (S. Muroi, published by KOBUNSHI-KANKOKAI, 1970).

The polymer latex has an average particle size of preferably from 1 to 50000 nm, and more preferably from 5 to 1000 nm. The particle size distribution of the latex may be polydisperse or monodisperse.

The polymer latex may be a conventional polymer latex with a uniform structure or a core-shell type polymer latex. In the core-shell type polymer latex, one may be preferred in which a polymer constituting the core is different in glass transition temperature from a polymer constituting the shell.

The minimum film forming temperature (MFT) of the polymer latex used in the invention is preferably from −30 to 90° C., and more preferably from 0 to 70° C. In the invention, a film forming aid may be added to control the minimum film forming temperature. Such a film forming aid is called a plasticizer, and is an organic compound (usually an organic solvent), which lowers the minimum film forming temperature of the polymer latex. Such an organic compound is described, for example, in S. Muroi, “Gousei Latex no Kagaku (Chemistry of Synthesized Latex)”, published by Koubunshi Kankoukai (1970).

### (Polymer Having Vinyl Alcohol Unit)

The polymer having a vinyl alcohol unit used in the subbing layer will be explained below.

In the present invention, as the polymer having a vinyl alcohol unit, there are mentioned polyvinyl alcohol and its derivative such as ethylene-vinyl alcohol copolymer, modified polyvinyl alcohol which is partially butyralized and dissolved in water, and so forth.

Polyvinyl alcohol preferably has a polymerization degree of not less than 100 and a saponification degree of not less than 60, and its derivatives include a polymer derived from a vinyl acetate copolymer having as the copolymerization component before saponification a monomer unit such as vinyl compounds such as ethylene, propylene, etc.; acrylic acid esters (for example, t-butylacrylate, phenylacrylate, 2-naphthylacrylate, etc.); methacrylic acid esters (for example, methylmethacrylate, ethylmethacrylate, 2-hydroxyethylmethacrylate, benzylmethacrylate, 2-hydroxypropylmethacrylate, phenylmethacrylate, cyclohexylmethacrylate, cresylmethacrylate, 4-chlorobenzylmethacrylate, ethyleneglycoldimethacrylate, etc.); acrylamides (for example, acrylamide, methylacrylamide, ethylacrylamide, propylacrylamide, butylacrylamide, tert-butylacrylamide, cyclohexylacrylamide, benzylacrylamide, hydroxymethylacrylamide, methoxyethylacrylamide, dimethylaminoethylacrylamide, phenylacrylamide, dimethylacrylamide, diethylacrylamide, β-cyanoethylacrylamide, diacetoneacrylamide, etc.); methacrylamides (for example, methacrylamide, methylmethacrylamide, ethylmethacrylamide, propylmethacrylamide, butylmethacrylamide, tert-butylmethacrylamide, cyclohexylmethacrylamide, benzylmethacrylamide, hydroxymethylmethacrylamide, methoxyethylmethacrylamide, dimethylaminoethylmethacrylamide, phenylmethacrylamide, dimethylmethacrylamide, diethylmethacrylamide, β-cyanoethylmethacrylamide, etc.); styrenes (for example, styrene, methylstyrene, dimethylstyrene, trimethylstyrene, ethylstyrene, isopropylstyrene, methoxystyrene, acetoxystyrene, chlorostyrene, dichlorostyrene, bromostyrene, vinylbenzoic acid methyl ester, etc.); divinylbenzene; acrylonitrile; methacrylonitrile, N-vinylpyrrolidone, N-vinyloxazolidone, vinylidene chloride; or phenyl vinyl ketone. Of these, ethylene-vinyl alcohol copolymer is preferred. The content of the polymer containing a polyvinyl alcohol unit in the upper subbing layer is 1 to 50% by weight, and preferably 5 to 30% by weight, based on the total binder weight of the upper subbing layer. The content of the polymer containing a polyvinyl alcohol unit in the upper subbing layer of less than 1% is not effective, while the content of the polymer containing a polyvinyl alcohol unit in the upper subbing layer of not less than 50%, the hydrophilicity is too high which results in lowering of printing durability at high humidity.

### (Others)

The following inorganic particles can be employed for the subbing layer preferably used in the present invention. Examples of the inorganic material include silica, alumina, barium sulfate, calcium carbonate, titania, tin oxide, indium oxide, and talk. These particle shapes are not particularly limited, and any shape such as needle-like, spherical, plate-like, or fracture-like shape can be used. The particle diameter is preferably 0.1 to 10 μm, more preferably 0.2 to 6 μm, and still more preferable 0.3 to 3 μm. The addition amount of particles is 0.1 to 50 mg per 1 m² of one surface, preferably 0.2 to 30 mg, and more preferably 0.3 to 20 mg.

Thickness of the subbing layer preferably used in the invention is preferably 0.05 to 0.50 μm in view of transparency and uneven coating (interference unevenness), and more preferably 0.10 to 0.30 μm. The thickness less than 0.05 μm cannot give an intended adhesion property, resulting in out of registration and lowering on-press developability and printing durability. The thickness exceeding 0.50 μm gives strong interference unevenness, which is commercially unacceptable.

As for the subbing layer, the coating liquid is coated onto either one surface or both surfaces of polyester film particularly before completing crystalline orientation during coating of a support, but it is preferable that the coating liquid is coated onto either one surface or both surfaces of polyester film in on line or off line after coating of a support.

As a coating method of the subbing layer, commonly known as appropriate coating-methods may be employed. It is preferable to apply the following method singly or in combination, for example, a kiss coating method, reverse coating method, die coating method, reverse kiss coating method, offset gravure coating method, the Meyer bar coating method, roller brush method, spray coating method, air-knife coating method, dip-coating method, and curtain coating method.

It is preferable to provide an antistatic layer for the subbing layer. The antistatic layer is made of an antistatic agent and a binder.

A metal oxide is preferably employed as an antistatic agent. Examples of such metal oxides preferably include ZnO, TiO₂, SnO₂, Al₂O₃, In₂O₃, SiO₂, MgO, BaO, MoO₂, and V₂O₅, as well as their multiple oxides. Specifically, from the viewpoint of miscibility with a binder, electrical conductivity and transparency, SnO₂ (being tin oxide) is preferred. As examples containing a different atom, Sb, Nb, or a halogen atom may be added to SnO₂. The added amount of the different atom is preferably in the range of 0.01 to 25 mol %, but the range of 0.1 to 15 mol % is specifically preferred. Tin oxide is preferably in the form of an amorphous sol or crystalline particles. In the case of a water based coating, an amorphous sol is preferred, and in the case of a solvent based coating, it is in the form of crystalline particles. Specifically, from the viewpoint of ecology and handling during operation, the amorphous sol form of a water based coating is preferred. A production method of the amorphous SnO₂ sol utilized for the present invention may be either of the following methods, a method to prepare by dispersing SnO₂ particles into an appropriate solvent, or a method to prepare via decomposition reaction of a solvent-soluble Sn compound in a solvent. The preparation via a decomposition reaction of a solvent-soluble Sn compound in the solvent will be described. The solvent-soluble compound means a compound containing an oxoanion such as K₂SnO₃.3H₂O, water-soluble halide compound such as SnCl₄ or a compound having a structure represented by R′₂SnR₂, R₃SnX or R₂SnX₂ including, for example, organometallic compound such as (CH₃)₃SnCl.(pyridine), (C₄H₉)₂Sn (O₂CC₂H₅)₂ and an oxo-salt such as Sn(SO₄)₂.2H₂O. Methods for preparing a SnO₂ sol using the solvent-soluble Sn compound include a physical method by dissolving in a solvent, followed by applying heat or pressure, chemical method by oxidation, reduction or hydrolysis, and a method of preparing a SnO₂ sol via an intermediate. A SnO₂ sol preparation method described in Japanese Patent Examined Publication No. 35-6616 will be described as an example. SnCl₄ is first dissolved in distilled water of 100 times in capacity, and a precipitate of Sn(OH)₄ is prepared as an intermediate. Ammonia water is added into this product so as to be mildly alkaline, and colloidal SnO₂ sol can be prepared subsequently by heating up until ammonia odor does not smell at all. Although water is employed as a solvent in the above example, various solvents including an alcohol solvent such as methanol, ethanol or isopropanol; an ether solvent such as tetrahydrofuran, dioxane or diethylether; an aliphatic organic solvent such as hexane or heptane; or an aromatic organic solvent such as benzene or pyridine can be used according to kinds of Sn compounds. The present invention is not limited to the solvents, but water or alcohols are preferably used.

On the other hand, crystalline particles are described in detail in Japanese Patent O.P.I. Publication Nos. 56-143430 and 60-258541. Production methods of these electrically conductive metal oxide particles may be any one of the following methods or a combination of them. The first method is one in which metal oxide particles are prepared by baking, after which the particles are heat treated under the presence of different kinds of atoms; the second is that different kinds of atoms are presented during preparation of metal oxide particles while baking; and the third being oxygen defect is introduced by a decrease of oxygen concentration during baking.

The average particle diameter of the primary particles employed in the present invention is 0.001 to 0.5 μm, but preferably 0.001 to 0.2 μm. The solid content coverage of the metal oxide employed in this invention is 0.05 to 2 g, but preferably 0.1 to 1 g. Further, the volume fraction of metal oxide in the antistatic layer of this invention is 8 to 40% by volume, but preferably 10 to 35% by volume. The above range may vary due to color, form and composition of metal oxide particles, but in view of transparency and electrical conductivity, the above range is preferred.

Preferable examples of binder also include polyester, acryl-modified polyester, polyurethane, acryl resin, vinyl resin, vinylidene chloride resin, polyethylene imine vinylidene resin, polyethylene imine, polyvinyl alcohol, modified polyvinyl alcohol, cellulose ester and gelatin.

### EXAMPLES

The present invention will be detailed employing the following examples, but the invention is not limited thereto. In these examples, “parts” represents “parts by weight, unless otherwise specified.

### Example 1

### Support

### (Preparation of Support)

### (Pet Resin)

Added to 100 parts by weight of dimethyl terephthalate, and 65 parts by weight of ethylene glycol, was 0.05 parts by weight of magnesium acetate anhydrate as an ester exchange catalyst, and an ester exchange reaction was conducted under commonly known practice. To the obtained product, added were 0.05 parts by weight of antimony trioxide and 0.03 parts by weight of trimethyl phosphate ester. Subsequently, subjected to a gradual temperature rise and pressure reduction, polymerization was conducted at 280° C. and at 0.5×9.8 Pa, to obtain polyethylene terephthalate (PET) resin having an intrinsic viscosity of 0.70.

Employing the PET resin as obtained above, biaxially stretched PET film was prepared as described below.

### (Biaxially Stretched Pet Film)

The PET resin was palletized and subjected to vacuum drying at 150° C. for 8 hours. After that, the resin was melt-extruded at 285° C. from a T die to form a layer, and the layer was electrostatically impressed on a 30° C. cooling drum while electrostatically impressed, and cooled to solidification, whereby unstretched film was obtained. This unstretched film was stretched at a factor of 3.3 in the longitudinal direction, employing a roll type longitudinal stretching machine. Subsequently, the resulting uniaxially stretched film, using a tenter type transverse stretching machine, was stretched at 90° C. by 50% of the total transverse stretch magnification in the first stretching zone, and then stretched at 100° C. in the second stretching zone so that the total transverse stretch magnification was 3.3. Further, the resulting film was preheated at 70° C. for two seconds, heat-set at 150° C. for five seconds in the first setting zone and at 220° C. for 15 seconds in the second setting zone, and relaxed at 160° C. by 5% in the transverse (width) direction. After passed through the tenter, the film was cooled to room temperature in 60 seconds, released from the clips, slit and wound around a core to obtain a 175 μm thick biaxially stretched PET film. The Tg of this biaxially stretched PET film was 79° C., and the thickness distribution of the film was 2%.

The one surface of the biaxially stretched PET film prepared above was subjected to corona discharge treatment at 8 W/m²·minute. Subsequently, the following subbing layer coating solution a-1 was coated on the support and dried at 123° C. to form on a hydrophilic layer side a subbing layer A-1 with a dry thickness of 0.8 μm.

The other surface of the biaxially stretched PET film was subjected to corona discharge treatment at 8 W/m²·minute, and the subbing layer coating solution b-1 was coated at 23° C. on the resulting surface and dried at 123° C. to form a subbing layer B-1 with a dry thickness of 0.1 μm, which had anti-static property.

Subsequently, both of the subbing layers A-1 and B-1 were subjected to corona discharge treatment at 8 W/m²·minute. After that, the subbing layer coating solution a-2 was coated on the resulting subbing layer A-1 and dried at 123° C. to form a subbing layer A-2 with a dry thickness of 0.1 μm, and the subbing layer coating solution b-2 was coated on the resulting subbing layer B-1 and dried at 123° C. to form a subbing layer B-2 with a dry thickness of 0.2 μm. The resulting support was further subjected to heat treatment at 140° C. for 2 minutes. Thus, sample with subbing layers was prepared.

(Subbing Layer Coating Solution a-1)
<<Subbing Layer Coating Solution a>>

| | | |
|---|---|---|
| Latex of styrene-glycidyl methacrylate-butyl | 250 | g |
| acrylate (60/39/1) copolymer (Tg = 75° C.) | | |
| (with a solid content of 30% by weight) | | |
| Latex of styrene-glycidyl methacrylate-butyl | 25 | g |
| acrylate (20/40/40) copolymer (Tg = 20° C.) | | |
| (with a solid content of 30% by weight) | | |
| Anionic surfactant S-1 (2%) | 30 | g |
| Water was added to make 1 kg. | | |

(Subbing Layer Coating Solution b-1)

| | | |
|---|---|---|
| *Metal oxide F-1 (SnO₂ sol, 8.3% by weight) | 109.5 | g |
| Latex of styrene-butyl acrylate- | 3.8 | g |
| hydroxymethacrylate (27/45/28) copolymer (Tg = 45° C.) | | |
| (with a solid content of 30% by weight) | | |
| Latex of styrene-glycidyl methacrylate-butyl | 15 | g |
| acrylate (20/40/40) copolymer (Tg = 20° C.) | | |
| (with a solid content of 30% by weight) | | |
| Anionic surfactant S-1 (2%) | 25 | g |
| Water was added to make 1 kg. | | |

### Preparation of *Metal Oxide F-1 (Colloidal Tin Oxide Dispersion)

Sixty five grams of stannic chloride hydrate were dissolved in 2000 ml of a mixture solution of water and ethanol to obtain a stannic chloride solution, and boiled to obtain a co-precipitate in the solution. The co-precipitate was taken out by decantation and washed several times by distilled water. After a silver nitrate solution was added to the distilled water used for washing the precipitate and a chloride ion was not confirmed in the distilled water, distilled water was added to the washed precipitate to make 2000 ml in total. The resulting aqueous mixture solution was added with 40 ml of aqueous 30% ammonia, concentrated by heating to 470 ml, and then added with 300 ml of water. Thus, colloidal tin oxide dispersion was prepared.

(Subbing Layer Coating Solution a-2)

| | | |
|---|---|---|
| Modified water-soluble polyester L-4 solution | 31 | g |
| (with a solid content of 23% by weight) | | |
| Aqueous 5 weight % solution of EXCEVAL RS-2117 | 58 | g |
| (vinyl alcohol-ethylene copolymer) produced by | | |
| Kuraray Co., Ltd. | | |
| Anionic surfactant S-1 (2% by weight) | 6 | g |
| Hardener H-1 (0.5% by weight) | 100 | g |
| 2% by weight dispersion of spherical silica | 10 | g |
| matting agent SEAHOSTAR KE-P50 produced by | | |
| Nippon Shokubai Co., Ltd.) | | |
| Distilled water was added to make 1000 ml. | | |

(Subbing Layer Coating Solution b-2)

| | | |
|---|---|---|
| Modified water-soluble polyester L-3 solution | 150 | g |
| (with a solid content of 18% by weight) | | |
| Anionic surfactant S-1 (2%) | 6 | g |
| 2% by weight dispersion of spherical silica | 10 | g |
| matting agent SEAHOSTAR KE-P50produced by | | |
| Nippon Shokubai Co., Ltd.) | | |
| Distilled water was added to make 1000 ml. | | |

### (Preparation of Water-Soluble Polyester A-1 Solution)

A mixture consisting of 35.4 parts by weight of dimethyl terephthalate, 33.63 parts by weight of dimethyl isophthalate, 17.92 parts by weight of sodium salt of dimethyl 5-sulfoisophthalate, 62 parts by weight of ethylene glycol, 0.065 parts by weight of calcium acetate monohydrate, and 0.022 parts by weight of manganese acetate tetrahydrate was subjected to ester exchange reaction at 170 to 220° C. under a flow of nitrogen while distilling out methanol. Thereafter, 0.04 parts by weight of trimethyl phosphate, 0.04 parts by weight of antimony trioxide, and 6.8 parts by weight of 4-cyclohexanedicarboxylic acid were added. The resulting mixture underwent esterification at a reaction temperature of 220 to 235° C. while distilling out a nearly theoretical amount of water. Thereafter, the reaction system was heated over a period of one hour under reduced pressure, and subjected to polycondensation under a maximum pressure of 133 Pa for 1 hour, while heated to a final temperature of 280° C. Thus, water-soluble polyester A-1 was prepared. The intrinsic viscosity of the polyester A-1 was 0.33.

Subsequently, 850 ml of pure water was placed in a 2-liter three-necked flask fitted with stirring blades, a refluxing cooling pipe, and a thermometer, and 150 g of the water-soluble polyester A-1 was gradually added while rotating the stirring blades. The resulting mixture was stirred at room temperature for 30 minutes, heated to 98° C. over a period of 1.5 hours, and maintained at that resulting temperature for 3 hours, whereby dissolution was performed. Thereafter, the mixture was cooled to room temperature over a period of one hour, and allowed to stand overnight, whereby a 15% by weight water-soluble polyester A-1 solution was prepared.

### (Preparation of Modified Water-Soluble Polyester Lx-3 Solution)

One thousand nine hundred milliliters of the foregoing 15% by weight water-soluble polyester A-1 solution were placed in a 3-liter four-necked flask fitted with stirring blades, a reflux cooling pipe, a thermometer and a dripping funnel, and heated to 80° C., while rotating the stirring blades. Into this added was 6.52 ml of a 24% aqueous ammonium peroxide solution, and a monomer mixture (consisting of 35.7 g of ethyl acrylate and 35.7 g of methyl methacrylate) was dropwise added over a period of 30 minutes, and the mixture was reacted for additional 3 hours. Thereafter, the reaction mixture was cooled to not more than 30° C., and filtrated. Thus, a modified water-soluble polyester Lx-3 solution having a solid content of 18% by weight was obtained.

### (Preparation of Water-Soluble Polyester L-4 Solution)

One thousand nine hundred milliliters of the foregoing 15% by weight water-soluble polyester A-1 solution were placed in a 3-liter four-necked flask fitted with stirring blades, a reflux cooling pipe, a thermometer and a dripping funnel, and heated to 80° C., while rotating the stirring blades. Into this added was 6.52 ml of a 24% aqueous ammonium peroxide solution, and a monomer mixture (consisting of 28.5 g of glycidyl methacrylate, 21.4 g of ethyl acrylate and 21.4 g of methyl methacrylate) was dropwise added over a period of 30 minutes, and the mixture was reacted for additional 3 hours. Thereafter, the reaction mixture was cooled to not more than 30° C., and filtrated. Thus, a modified water-soluble polyester B-1 (with a vinyl component modified rate of 20% by weight) solution having a solid content of 18% by weight was obtained. Further, a modified water-soluble polyester L-4 solution with a vinyl component modified rate of 8% by weight was prepared.

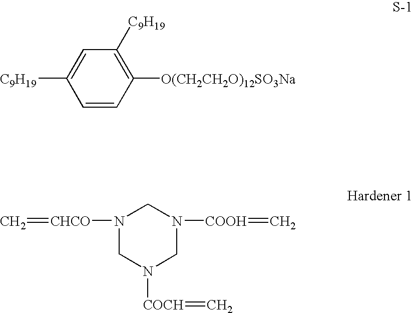

### (Preparation of Back Coat Layer Solution)

Materials in the composition as shown in the following Table were sufficiently mixed while stirring, employing a homogenizer, and filtered to obtain a back coat layer coating solution.

TABLE 1

| | Addition | |
|---|---|---|
| Materials | Amount | |
| Colloidal silica: Snowtex XS (solid content 20% | 33.60 | g |
| by weight, produced by Nissan Kagaku Co., Ltd.) | | |
| Acryl emulsion: DK-05 (solid content: 20% by | 14.00 | g |
| weight, produced by Gifu Shellac Co., Ltd.) | | |
| Matting agent (PMMA with an average particle | 0.56 | g |
| size of 5.5 μm) | | |
| Pure water | 51.84 | g |
| Solid content (% by weight) | 14 | wt. % |

### (Coating of Back Coat Layer Coating Solution)

The back coat layer coating solution was coated, through a wire bar #6, on the subbing layer surface B of each of the subbed supports and allowed to pass through a 120° C. drying zone with a length 15 m at a transportation speed of 50 m/minute to form a back coat layer. The coating amount of the back coat layer was 1.8 g/m².

### (Preparation of Lower Hydrophilic Layer Coating Solution)

Materials of the composition in the following Table were sufficiently mixed while stirring, employing a homogenizer, and filtered to obtain a lower hydrophilic layer coating solution.

TABLE 2

| | Solid | |
|---|---|---|
| | Content | |
| Materials | (Wt. %) | g/1 kg |
| Porous metal oxide particles Silton JC 40 | 100 | 22 |
| Water-swelled gel prepared by vigorously | 5 | 44 |
| stirring layer structural clay mineral | | |
| montmorillonite, Mineral Colloid MO (porous | | |
| aluminosilicate particles with an average | | |
| particle size of 4 μm, produced by Mizusawa | | |
| Kagaku Co., Ltd.) in water in a homogenizer | | |
| to give a solid content of 5% by weight | | |
| Aqueous dispersion of Cu—Fe—Mn type metal | 40 | 100 |
| oxide black pigment, TM-3550 black powder | | |
| (produced by Dainichi Seika Kogyo Co., | | |
| Ltd.) with a particle size of 0.1 μm having | | |
| a solid content of 40% by weight (including | | |
| 0.2% by weight of dispersant) | | |
| Carboxymethyl cellulose (produced by Kanto | 4 | 28 |
| Kagaku Co., Ltd.) | | |
| Trisodium phosphate•dodecahydrate (produced | 10 | 5.6 |
| by Kanto Kagaku Co., Ltd.) | | |
| Colloidal silica: Snowtex XS (solid content | 20 | 528.2 |
| 20% by weight, produced by Nissan Kagaku | | |
| Co., Ltd.) | | |
| Colloidal silica: Snowtex ZL (solid content | 40 | 17.1 |
| 40% by weight, produced by Nissan Kagaku | | |
| Co., Ltd.) | | |
| Surface-coated melamine resin particles: | 100 | 33 |
| STM-6500S (produced by Nissan Kagaku Co., | | |
| Ltd.) with an average particle size of 6.5 | | |
| μm | | |
| RS-2117 EXCEVAL (vinyl alcohol-ethylene | 5 | 130 |
| copolymer) produced by Kuraray Co., Ltd. | | |
| FZ-2161 Silicon-containing surfactant | 20 | 8.8 |
| (Produced by Nippon Unicar Co., Ltd.) | | |
| Pure Water | | 83.3 |
| Total weight (g) | | 1000 |

### (Preparation of Upper Hydrophilic Layer Coating Solution)

Materials of the composition in the following Table were sufficiently mixed while stirring, employing a homogenizer, and filtered to obtain a upper hydrophilic layer coating solution.

TABLE 3

| | Addition | |
|---|---|---|
| Materials | Amount | |
| Colloidal silica (alkaline): Snowtex S (solid | 5.2 | g |
| content 30% by weight, produced by Nissan Kagaku | | |
| Co., Ltd.) | | |
| Necklace shaped colloidal silica (alkaline): | 14.0 | g |
| Snowtex PSM (solid 20% by weight, produced by | | |
| Nissan Kagaku Co., Ltd.) | | |
| Colloidal silica (alkaline): MP-4540 (having an | 4.5 | g |
| average particle size of 0.4 μm, solid content | | |
| 30% by weight, produced by Nissan Kagaku Co., | | |
| Ltd.) | | |
| Porous metal oxide particles Silton JC-20 (porous | 1.2 | g |
| aluminosilicate particles having an average | | |
| particle size of 2 μm, produced by Mizusawa | | |
| Kagaku Co., Ltd.) | | |
| Porous metal oxide particles Silton AMT 08 | 3.6 | g |
| (porous aluminosilicate particles having an | | |
| average particle size of 0.6 μm, produced by | | |
| Mizusawa Kagaku Co., Ltd.) | | |
| Water-swelled gel prepared by vigorously stirring | 4.8 | g |
| layer structural clay mineral, montmorillonite, | | |
| Mineral Colloid MO (produced by Southern Clay | | |
| Products Co., Ltd.) with an average particle size | | |
| of 0.1 μm) in water in a homogenizer to give a | | |
| solid content of 5% by weight | | |
| Aqueous dispersion of Cu—Fe—Mn type metal oxide | 2.7 | g |
| black pigment, TM-3550 black powder (produced by | | |
| Dainichi Seika Kogyo Co., Ltd.) with a particle | | |
| size of 0.1 μm having a solid content of 40% by | | |
| weight (including 0.2% by weight of dispersant) | | |
| Aqueous 4% by weight solution of sodium | 3.0 | g |
| carboxymethyl cellulose (produced by Kanto Kagaku | | |
| Co., Ltd.) | | |
| Aqueous 10% by weight solution of trisodium | 0.6 | g |
| phosphate•dodecahydrate (reagent produced by | | |
| Kanto Kagaku Co., Ltd.) | | |
| Pure Water | 62.7 | g |
| Solid content (% by weight) | 12 | wt. % |

### (Coating of Lower and Upper Hydrophilic Layer Coating Solutions)

The lower hydrophilic layer coating solution was coated, through a wire bar #5, on the rear surface (subbing layer surface A side) of each of the resulting supports obtained above, and allowed to pass through a 120° C. drying zone with a length 15 m at a transportation speed of 40 m/minute to form a lower hydrophilic layer. Successively, the upper hydrophilic layer coating solution was coated on the resulting lower hydrophilic layer employing a wire bar #3, and allowed to pass through a 120° C. drying zone with a length 30 m at a transportation speed of 40 m/minute to form an upper hydrophilic layer. The coating amount of the lower layer and that of the upper layer were 3.0 g/m² and 0.55 g/m², respectively. The resulting support samples were further subjected to aging treatment at 60° C. for 48 hours.

### (Preparation of Image Formation Layer Coating Solution)

### (1) Preparation of Heat Fusible Particles and Heat Fusible Particle Dispersion

Heat melting compound and heat softening compound were mixed in a combination (mixed ratio) as shown in Table 4 while heating to obtain a fused mixture. The fused mixture of 20 g was dropwise added to a dispersion medium comprised 72 g of water, 5 g of polyoxyethylene nonylphenyl ether and 3 g of triethanolamine while stirring. Thus, heat fusible particle dispersion Nos. 1 through 11 containing heat fusible particles were prepared which had an effective solid content of 20% by weight. In the preparation above, the medium temperature, addition speed, stirring strength and stirring time were controlled to give particles with an average particle size of from 0.5±0.1 μm.

TABLE 4

| Heat Fusible Particles and Heat Fusible Particle Dispersion | | | | | | | |
|---|---|---|---|---|---|---|---|
| | | | Mixed | Heat | | Mixed | |
| | Heat Melting | m.p. | ratio | Softening | s.p. | ratio | Re- |
| No. | Compound | (° C.) | (wt. %) | Compound | (° C.) | (wt. %) | marks |
| 1 | Carnauba wax | 72 | 90 | (a) | 88 | 10 | Inv. |
| | (Carnauba No. 1) | | | | | | |
| 2 | Carnauba wax | 72 | 90 | (b) | 70 | 10 | Inv. |
| 3 | Carnauba wax | 72 | 90 | (c) | 100 | 10 | Inv. |
| 4 | Paraffin wax HNP-3 | 64 | 90 | (d) | 150 | 10 | Inv. |
| | (produced by Nippon | | | | | | |
| | Seiro Co., Ltd.) | | | | | | |
| 5 | Paraffin wax | 64 | 90 | (e) | 125 | 10 | Inv. |
| 6 | ″ | 64 | 90 | (f) | 70 | 10 | Inv. |
| 7 | Carnauba wax | 72 | 60 | (a) | 88 | 40 | Inv. |
| | (Carnauba No. 1) | | | | | | |
| 8 | Carnauba wax | 72 | 40 | (a) | 88 | 60 | Comp. |
| | (Carnauba No. 1) | | | | | | |
| 9 | Carnauba wax | 72 | 97 | (a) | 88 | 3 | Comp. |
| | (Carnauba No. 1) | | | | | | |
| 10 | Paraffin wax HNP-3 | 64 | 90 | (g) | 165 | 10 | Comp. |
| | (produced by Nippon | | | | | | |
| | Seiro Co., Ltd.) | | | | | | |
| 11 | Paraffin wax | 55 | 90 | (e) | 125 | 10 | Comp. |
| | Paraffin 130 | | | | | | |
| | (produced by Nippon | | | | | | |
| | Seiro Co., Ltd.) | | | | | | |

Inv.: Inventive, Comp.: Comparative, s.p.: softening point
(a) Low density polyethylene UBE Polyethylene L719 (produced by Ube Kosan Co., Ltd.)
(b) Ethylene ethylacrylate copolymer A-701 (produced by Mitsui Dupont Polychemicals Co., Ltd.)
(c) Novolak resin Tamanol 579 (produced by ARAKAWA CHEMICAL INDUSTRIES, LTD.)
(d) Terpene phenol resin Tamanol 803L (produced by ARAKAWA CHEMICAL INDUSTRIES, LTD.)
(e) Alicyclic saturated hydrocarbon resin Arkon P125 (produced by ARAKAWA CHEMICAL INDUSTRIES, LTD.)
(f) Ethylene vinyl acetate copolymer P-1007 (produced by Mitsui Dupont Polychemicals Co., Ltd.)
(g) Polymerized rosin ester Pensel KK (produced by ARAKAWA CHEMICAL INDUSTRIES, LTD.)

### (2) Thermosensitive Image Formation Layer

The thermosensitive image formation layer coating solutions A, B and C, having the thermosensitive image formation layer compositions A, B and C as shown in the following Table 5, respectively, were prepared. The resulting solution had a solid content of 10% by weight. The resulting image formation layer coating solution was coated on the upper hydrophilic layer obtained above through a wire bar #5, as shown in Table 7, and allowed to pass through a 70° C. drying zone with a length of 30 m at a transportation speed of 50 m/minute to form an image formation layer. Thus, planographic printing plate material samples 1 through 13 were prepared. The coating amount of the thermosensitive image formation layer was 0.5 g/m². The resulting samples were subjected to aging treatment at 50° C. for 24 hours.

TABLE 5
Image Formation Layer (Coating Solution 1)

| | A | B | C |
|---|---|---|---|
| Materials used | (wt. %) | (wt. %) | (wt. %) |
| Carnauba wax dispersion A118 | 50 | 65 | 70 |
| (produced by Gifu Shellac | | | |
| Manufacturing Co., Ltd.) | | | |
| Microcrystalline wax dispersion | 10 | 10 | 15 |
| A206 (produced by Gifu Shellac | | | |
| Manufacturing Co., Ltd.) | | | |
| Heat Fusible Particle Dispersion | 30 | 15 | 5 |
| Nos. 1-11 | | | |
| Sodium polyacrylate DL-522 | 8 | 8 | 8 |
| (produced by Nippon Shokubai Co., | | | |
| Ltd.) | | | |
| Penon JE-66 (produced by Nippon | 2 | 2 | 2 |
| Starch Chemical Co., Ltd.) | | | |
| Remarks | Inv. | Inv. | Comp . |

Inv.: Inventive, Comp.: Comparative

For comparison, the thermosensitive image formation layer coating solutions D, E and F, having the thermosensitive image formation layer compositions D, E and F as shown in the following Table 6, respectively, were prepared. The resulting solution had a solid content of 10% by weight. Planographic printing plate material samples 14 through 16 were prepared in the same manner as the Planographic printing plate material samples 1 through 13, except that the thermosensitive image formation layer coating solutions D, E and F were used instead of the thermosensitive image formation layer coating solutions A, B and C.

TABLE 6
Image Formation Layer (Coating Solution 2)

| | D | E | F |
|---|---|---|---|
| Materials used | (wt. %) | (wt. %) | (% wt. %) |
| Carnauba wax dispersion A118 | 70 | 65 | 40 |
| (produced by Gifu Shellac | | | |
| Seizousho Co., Ltd.) | | | |
| Microcrystalline wax dispersion | 20 | 15 | 10 |
| A206 (produced by Gifu Shellac | | | |
| Seizousho Co., Ltd.) | | | |
| *Low density polyethylene | 0 | 10 | 40 |
| dispersion of polyethylene L719 | | | |
| (produced by Ube Kosan Co., Ltd.) | | | |
| Sodium polyacrylate DL-522 | 8 | 8 | 8 |
| (produced by Nippon Shokubai Co., | | | |
| Ltd.) | | | |
| Penon JE-66 (produced by Nippon | 2 | 2 | 2 |
| Starch Chemical Co., Ltd.) | | | |
| Remarks | Comp. | Comp. | Comp. |

Inv.: Inventive, Comp.: Comparative
*Low density polyethylene dispersion is a dispersion obtained by dispersing the following composition in a ball mill to give an average particle size of 0.5 μm.

| | |
|---|---|
| Polyethylene L719 available from Ube Kosan | 10 g |
| Polyoxyethylene nonylphenyl ether | 5 g |
| Water | 85 g |

The resulting planographic printing plate material was cut into a 730 mm width, and wound around a paper core with an outside diameter of 76 mm by a length of 30 m. Thus, planographic printing plate material samples 1 through 16 in roll were obtained.

### <<Evaluation>>

### (Exposure)

Each of the resulting printing plate material samples was exposed employing a plate setter equipped with a semiconductor laser (SS-830 produced by Konica Minolta MG Inc. to obtain various dot images with a screen line number of 175 lines.

### (Printing Method)

Each of the exposed printing plate material samples was mounted on a plate cylinder of a printing press DAIYA F-1 produced by Mitsubishi Heavy Industries, Ltd., and printing was carried out supplying printing ink, Toyo Hyunity Magenta (produced by Toyo Ink Manufacturing Co.) and dampening water, 2 wt. % of Astromark 3 (produced by Nikken Kagaku Kenkyusho) to the printing plate material sample. Images were printed on an obverse surface of a fresh printing paper sheet, while spraying, on the printing paper sheet obverse surface, powder (Trade name: Nikkariko M, produced by Nikka Ltd.) at a printing press powder scale of 10, and then on the rear surface of the printing paper sheet.

The resulting printed sheet was observed for evaluation of the planographic printing plate material samples obtained above.

### (Sensitivity)

In the above exposure, exposure energy was changed from 150 to 350 mJ/cm² by controlling a rotational number of the exposure drum of the plate setter and laser output power. The minimum exposure energy at which stable printing durability was obtained from the printing evaluation result was defined as sensitivity.

### (On-Press Development Property)

Printing was carried out according to the printing conditions described above, and the number of printed copies (waste papers) consumed from when printing started until when a print having an excellent S/N ratio was obtained was evaluated as a measure of on-press development property. The print having an excellent S/N ratio refers to one in which no background contamination was observed at non-image portions, showing that an image formation layer at non-image portions was completely removed on the press, and image density at image portions was in an appropriate range. The less the number is, the better the on-press development property. The number not less than 40 is practically problematic.

### (Printing Durability)

Printing terminated when either lack of dots at the 3% dot image portion or density reduction at solid image portions was observed was confirmed. The number of printed copies printed until the printing termination was determined as a measure of printing durability.

### (Resistance to Fogging by Pressure)

The image formation layer surface of the samples before exposure was rubbed by using a 0.5 mmφ sapphire needle with a 200 g load applied, and the ink contamination level at the non-image portions of a 20^{th} printed paper sheet was determined according to the following criteria, and was evaluated as a measure of resistance to fogging by pressure.

A: No ink contamination was observed at the non-image portions.
B: Slight ink contamination was observed at the non-image portions.
C: Ink contamination was observed at the non-image portions.

The results are shown in Table 7.

TABLE 7

| | | | Evaluation Results | | | | |
|---|---|---|---|---|---|---|---|
| | Heat Fusible | | | On-press | Print- | | |
| | Particles/ | | | Develop- | ing | Resis- | |
| Sam- | Heat Fusible | Image | Sensi- | ment | Dura- | tance to | |
| ple | Particle | Formation | tivity | Property | bility | fogging by | Re- |
| No. | Dispersion | Layer | (mJ/cm²) | (Number) | (Number) | pressure | marks |
| 1 | 1 (Inv.) | A (Inv.) | 270 | 15 | 24,000 | A | Inv. |
| 2 | 1 (Inv.) | B (Inv.) | 250 | 25 | 22,000 | A | Inv. |
| 3 | 1 (Inv.) | C (Comp.) | 230 | 20 | 16,000 | C | Comp. |
| 4 | 2 (Inv.) | B (Inv.) | 240 | 15 | 24,000 | A | Inv. |
| 5 | 3 (Inv.) | B (Inv.) | 250 | 20 | 23,000 | A | Inv. |
| 6 | 4 (Inv.) | B (Inv.) | 250 | 15 | 22,000 | A | Inv. |
| 7 | 5 (Inv.) | B (Inv.) | 280 | 15 | 21,000 | A | Inv. |
| 8 | 6 (Inv.) | B (Inv.) | 220 | 10 | 21,000 | A | Inv. |
| 9 | 7 (Inv.) | B (Inv.) | 290 | 25 | 21,000 | A | Inv. |
| 10 | 8 (Inv.) | B (Inv.) | 300 | 30 | 20,000 | A | Inv. |
| 11 | 9 (Inv.) | B (Inv.) | 230 | 15 | 19,000 | B | Inv. |
| 12 | 10 (Comp.) | B (Inv.) | 340 | 60 | 19,000 | A | Comp. |
| 13 | 11 (Comp.) | B (Inv.) | 240 | 15 | 14,000 | B | Comp. |
| 14 | — | D (Comp.) | 250 | 15 | 15,000 | C | Comp. |
| 15 | — | E (Comp.) | 310 | 25 | 18,000 | B | Comp. |
| 16 | — | F (Comp.) | 360 | 60 | 16,000 | A | Comp. |

Inv.: Inventive, Comp.: Comparative

As is apparent from Table 7, the inventive planographic printing plate material samples comprising a thermosensitive image formation layer containing heat melting particles having a specific composition provide printing properties that excel in printing durability in the printing employing a blocking powder and in resistance to fogging by pressure at non-image portions, without lowering sensitivity or on-press developing property.

1-4. (canceled)

5. A planographic printing plate material of on-press development type comprising a support and provided thereon, a hydrophilic layer and a thermosensitive image formation layer, wherein the thermosensitive image formation layer contains heat fusible particles in an amount of not less than 10% by weight based on the total solid content of the thermosensitive image formation layer, the heat fusible particles comprising a heat melting compound having a melting point of from 60 to 100° C. and a heat softening compound having a softening point of from 70 to 150° C.

6. The planographic printing plate material of claim 5, wherein the thermosensitive image formation layer contains heat fusible particles in an amount of from 10 to 60% by weight based on the total solid content of the thermosensitive image formation layer.

7. The planographic printing plate material of claim 5, wherein the average particle size of the heat fusible particles is from 0.1 to 1.0 μm.

8. The planographic printing plate material of claim 5, wherein the thermosensitive image formation layer further contains a water soluble material.

9. The planographic printing plate material of claim 5, wherein the hydrophilic layer contains metal oxide particles.

10. The planographic printing plate material of claim 5, wherein the hydrophilic layer contains a light-to-heat conversion material.

11. The planographic printing plate material of claim 10, wherein the light-to-heat conversion material is selected from black iron oxide and black complex metal oxides containing at least two different metals.

12. The planographic printing plate material of claim 5, wherein the support is a polyethylene naphthalate film or polyethylene terephthalate film.

13. The planographic printing plate material of claim 5, wherein the content ratio by weight of the heat melting compound to the heat softening compound in the heat fusible particles is from 97:3 to 50:50.

14. The planographic printing plate material of claim 5, wherein the heat fusible particles are obtained by mixing the heat melting compound with the heat softening compound, heat melting the resulting mixture, and dispersing the heat melted mixture in a dispersion medium.

15. A printing process comprising the steps of: forming an image on the planographic printing plate material of claim 5, employing a thermal head or a thermal laser;
mounting the resulting planographic printing plate material on a printing press; and
developing the resulting planographic printing plate material on the printing press by supplying dampening water or both of dampening water and printing ink to the planographic printing plate material, followed by printing.
